(19) United States
(12) Patent Application Publication
(10) Pub. No.: US 2026/0279475 A1
(43) Pub. Date: Sep. 17, 2026

(54) SELF-HEATING NAND FOR RECOVERY AT END OF LIFE

(71) Applicant: Sandisk Technologies, Inc., Milpitas, CA (US)

(72) Inventors: Albert Bor Kai Chen, Milpitas, CA (US); Jiahui Yuan, Fremont, CA (US); Yiwen Qian, Milpitas, CA (US); Peng Zhang, San Jose, CA (US); Rotem Sela, Hod Hasharon (IL)

(73) Assignee: Sandisk Technologies, Inc., Milpitas, CA (US)

(21) Appl. No.: 19/080,704

(22) Filed: Mar. 14, 2025

(51) Int. Cl. G11C 16/34; G11C 16/10; G11C 16/14

(52) U.S. Cl. CPC G11C 16/349; G11C 16/102; G11C 16/14; G11C 16/3418

(57) ABSTRACT

Technology for recovery of NAND memory from excessive wear. The recovery may be performed when the NAND memory is at or near its end of life. An aspect includes creating a current through the NAND channel of one or more victim NAND strings in a memory structure to heat a region of the memory structure having target NAND strings. The current through the NAND channel of the one or more victim NAND strings is regulated to maintain the temperature of the region of the memory structure having the target NAND strings to a target range of temperatures for a period of time to remove trapped charges from the memory cells on the target NAND strings.

### BACKGROUND

The present disclosure relates to non-volatile storage.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

Modern storage systems such as, for example, solid state drives typically contain a number of semiconductor dies with each die containing memory cells such as NAND strings. Each die may contain one or more planes with each plane containing a large number of blocks. Each block contains a large number of memory cells such as NAND strings. A NAND string contains memory cell transistors connected in series, a drain side select gate at one end, and a source side select gate at the other end. Each NAND string is associated with a bit line. The block typically has many word lines that provide voltages to the control gates of the memory cell transistors. In some architectures, each word line connects to the control gate of one memory cell on each respective NAND string in the block. The block is associated with a source line. The source side select gates are used to connect or disconnect the NAND channels from the source line.

The memory cells are programmed one group at a time. The unit of programming is typically referred to as a page. Typically, the memory cells are programmed to a number of data states. Using a greater number of data states allows for more bits to be stored per memory cell. For example, four data states may be used to store two bits per memory cell, eight data states may be used in order to store three bits per memory cell, 16 data states may be used to store four bits per memory cell, etc. Some memory cells may be programmed to a data state by storing charge in the memory cell. For example, the threshold voltage (Vt) of a NAND memory cell can be set to a target Vt by programming charge into a charge storage region such as a charge trapping layer. The amount of charge stored in the charge trapping layer establishes the Vt of the memory cell. When a NAND memory cell transistor is programmed, electrons are stored in a portion of the charge-trapping layer which is associated with the NAND memory cell transistor. These electrons are drawn into the charge-trapping layer from the channel, and through the tunneling layer. The Vt of a data memory cell transistor is increased in proportion to the amount of stored charge. The NAND memory cells are erased prior to programming. During an erase operation, the electrons from the charge-trapping layer return to the channel.

The NAND memory cells may undergo a large number of program/erase cycles. Electrons can get trapped in the tunneling layer during a program or erase operation. Over many program/erase cycles a significant number of electrons can get trapped in the tunneling layer thereby having a negative impact on the operation of the NAND memory cell. In some cases the memory cell may fail to properly program or erase, leading to a fail bit.

It has been proposed to use heat to recover fail bits by exposing the NAND memory cells to high temperature for a period of time.

Challenges remain in executing thermal recovery of NAND memory that results in a high recovery of fail bits, does not damage the NAND, and is cost effective.

### BRIEF DESCRIPTION OF THE DRAWINGS

Like-numbered elements refer to common components in the different figures.

FIG. 1 is a graph showing possible relationships between recovery percentage and write/erase cycles for different anneal times.

FIG. 2A is a block diagram depicting one embodiment of a storage system.

FIG. 2B is a block diagram of one embodiment of a memory die.

FIG. 2C is a block diagram of one embodiment of an integrated memory assembly.

FIGS. 3A and 3B depict different embodiments of integrated memory assemblies.

FIG. 3C is a block diagram depicting one embodiment of a portion of column control circuitry that contains a number of read/write circuits.

FIG. 4 is a perspective view of a portion of one example embodiment of a monolithic three dimensional memory structure.

FIG. 4A is a block diagram of one embodiment of a memory structure having two planes.

FIG. 4B is a block diagram depicting a top view of a portion of block of memory cells.

FIG. 4C depicts an embodiment of a stack showing a cross-sectional view along line AA of FIG. 4B.

FIG. 4D depicts a view of the region 445 of FIG. 4C.

FIG. 4E is a schematic diagram of a portion of one embodiment of a block, depicting several NAND strings.

FIGS. 5A and 5B depicts threshold voltage distributions.

FIG. 6 is a flowchart describing one embodiment of a process for programming memory cells.

FIG. 7 depicts how trapped electrons in a target cell may be removed, in an embodiment, by using a victim cell to heat the target cell.

FIG. 8 depicts a portion of a block of NAND memory cells to illustrate principles of an embodiment of self-heating NAND using victim cells.

FIG. 9 is a flowchart of one embodiment of a process of self-heating NAND using victim NAND strings to remove trapped charges in the memory cells of target NAND strings.

FIG. 10 is a flowchart of one embodiment of a process of setting up conditions of the NAND strings prior to self-heating NAND for recovery.

FIG. 11A depicts an embodiment of a system for recovery of NAND memory cells using self-heating by victim NAND strings.

FIG. 11B depicts an embodiment of a system for recovery of NAND memory cells using self-heating by victim NAND strings that uses a switch external to the die having the memory cells.

FIG. 12 is a flowchart of one embodiment of a process of self-heating NAND with victim NAND strings for recovery of memory cells on target NAND strings.

FIG. 13 is a flowchart of one embodiment of a process of self-heating NAND with victim NAND strings for recovery of memory cells on target NAND strings.

FIG. 14 shows an example pulse train that oscillates between a Vmax and Vmin.

FIG. 15 depicts example signals that may be applied to the bit line in an embodiment.

FIG. 16 depicts victim NAND string current versus control gate voltage for erased cells and a random pattern.

### DETAILED DESCRIPTION

Technology is disclosed for recovery of NAND memory from excessive wear. The recovery may be performed when the NAND memory is at or near its end of life. The recovery may be performed in a controlled setting on NAND memory devices that have been used by consumers. Optionally, the recovery may be performed in-the field. An embodiment of the recovery process involves self-heating of the NAND to remove trapped charges from memory cells. The recovery is useful to extend the life of the NAND to reduce waste, as otherwise the NAND may be discarded. Note that this recovery is not intended to recover data in the NAND, as the heat may result in data loss.

An embodiment includes creating a current through the NAND channel of one or more victim NAND strings in a memory structure to heat a region of the memory structure having target NAND strings. The current through the NAND channel of the one or more victim NAND strings is regulated to maintain the temperature of the region of the memory structure having the target NAND strings to a target range of temperatures for a period of time to remove trapped charges from the memory cells on the target NAND strings. Removing the trapped charges allows the NAND memory cells to continue to be used, thereby extending the life of the NAND memory cells to reduce waste.

The self-heating of NAND using the victim NAND strings can recover a high percentage of fail bits. The self-heating of NAND using the victim NAND strings can recover a high percentage of fail bits without damaging the NAND. The self-heating of NAND using the victim NAND strings is cost effective way to recover a high percentage of fail bits. The self-heating of NAND using the victim NAND strings is compatible with circuitry typically used for memory operations.

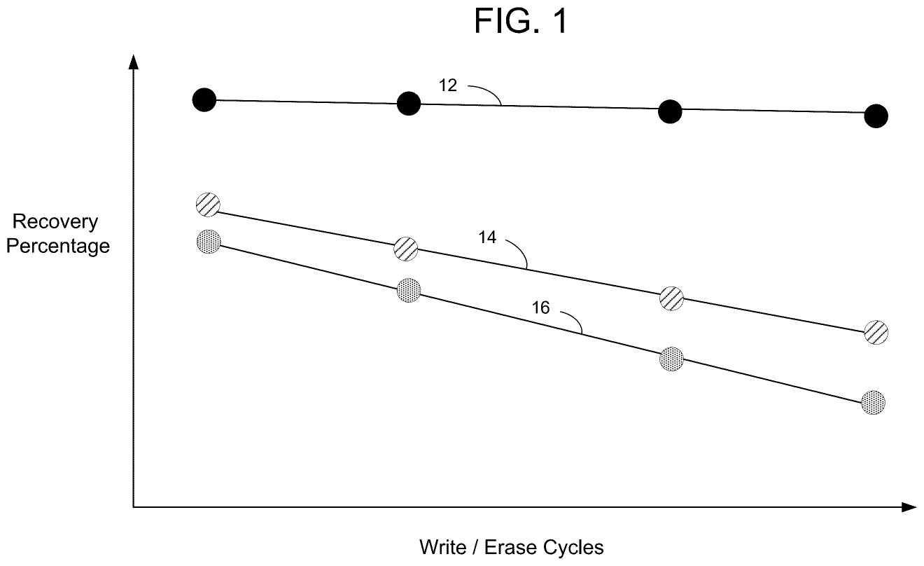

FIG. 1 is a graph showing possible relationships between recovery percentage and write/erase cycles for different anneal times. Plot 12 is for the longest anneal time of the three, plot 106 is for the shortest anneal time of the three, with plot 14 being for an anneal time between the longest and shortest. All three plots are for the same anneal temperature. Using a long anneal time (plot 12) can lead to a very high recovery of fail bits even with a high write/erase cycle count. Even a short anneal time (plot 16) can lead to a fairly high recovery of fail bits for lower write/erase cycle counts. For higher write/erase cycle counts a short anneal time may still provide for recovery of some of the fail bits.

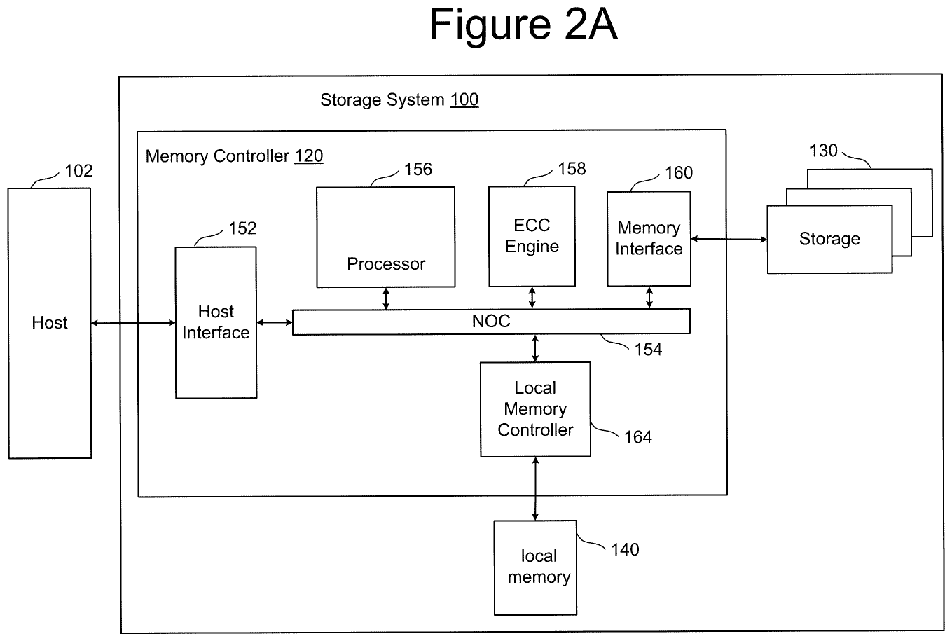

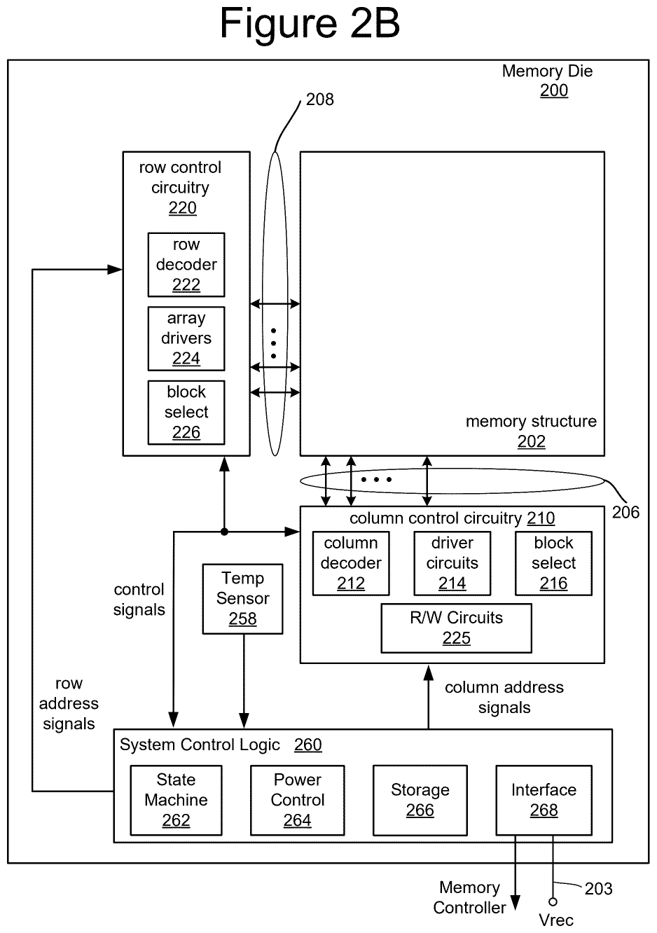

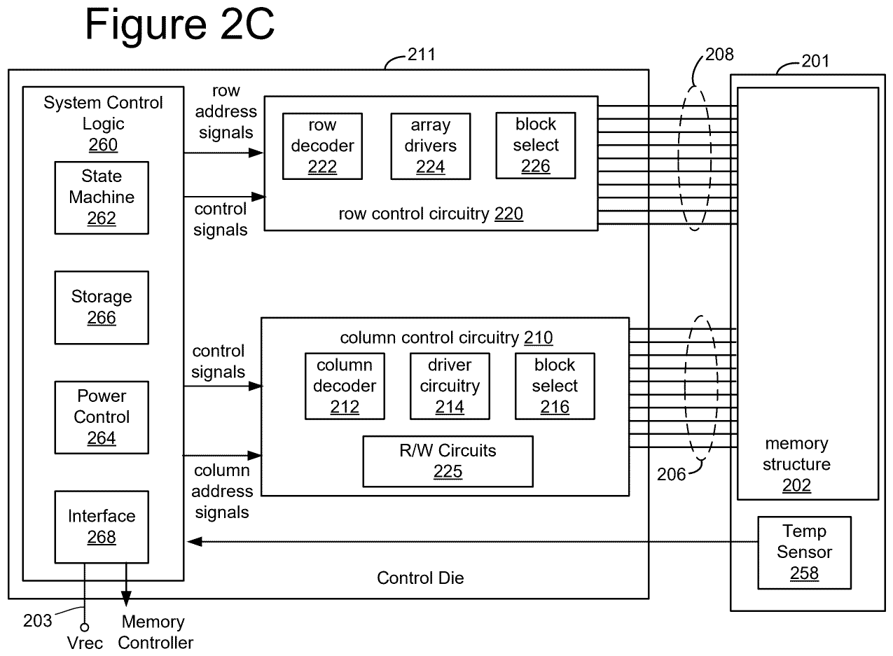

FIG. 2A is a block diagram of one embodiment of a storage system 100 that may implement the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 2A are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

In an embodiment, the memory controller 120 initiates self-heating in the storage 130 for recovery at the end of life of the storage 130. The memory controller 120 may provide a voltage to the storage 130 that is applied to one or more bit lines connected to one or more victim NAND strings. The victim NAND strings generate currents that are used to heat the storage 130 for recovery at the end of life of the storage 130. For example, charges may be de-trapped from tunneling layers of NAND memory cells.

In one embodiment, non-volatile storage 130 comprises one or more memory dies. FIG. 2B is a functional block diagram of one embodiment of a memory die 200 that comprises non-volatile storage 130. Each of the one or more memory dies of non-volatile storage 130 can be implemented as memory die 200 of FIG. 2B. The components depicted in FIG. 2B are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic circuit 260, and typically may include such circuits as row decoders 222, array drivers 224, and block select circuitry 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only single block is shown for structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers. The system control logic 260, column control circuitry 210, and/or row control circuity 220 are configured to control memory operations such as open block reads at the die level.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202. The memory die 200 also includes a temperature sensor 258, which is configured to sense temperature on the memory die 200 and report the temperature to the system control logic 260. The temperature sensor 258 may include a TCO (Temperature Coefficient) BGR (band gap reference). The location of the temperature sensor 258 is not limited to a particular area of the memory die 200. Thus, it will be understood that the location of the temperature sensor 258 is not limited to the region depicted in FIG. 2B. There may be more than one temperature sensors 258 on the memory die 200. The temperature sensor 258 may be used during memory operations such as read and program to perform temperature dependent operations. For example, the magnitude of voltages during read and/or program operations may depend on the temperature. In an embodiment, the temperature sensor 258 is used to sense temperature during a recovery of memory cells that uses self-heating. The temperature sensor 258 may be used to keep the temperature within a target range that is suitable for de-trapping charges in memory cells at or near the end of life.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used. There is a pin or pad 203, which may be a part of the memory controller interface 268. The pin/pad 203 could be one that is used to provide a voltage to the NAND die. An example is a Vpp pin in the Open NAND Flash Interface (ONFI). In an embodiment, a recovery voltage (Vrec) is provided to the pin/pad 203. The recovery voltage (Vrec) may be provided to a bit line of a victim NAND string (with suitable voltages to the source line, select gates, and word lines) to generate a current in the victim NAND string to heat a region of the memory structure 202 near the victim NAND string. The voltage Vrec is provided from a power source that is capable of providing a large enough current to heat at least a region of the memory structure 202 having target NAND strings to a target temperature (e.g., 250 degrees Celsius) for self-heating to remove the trapped charges from the memory cells on the target NAND strings. In an embodiment, Vrec is provided from the memory controller 120. However, Vrec may be provided from a source other than memory controller 120 if the NAND is being recovered in a test or refurbishment environment or the like at the end of life.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2B can be grouped into two parts: (1) memory structure 202 and (2) peripheral circuitry, which includes all of the other components depicted in FIG. 2B. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

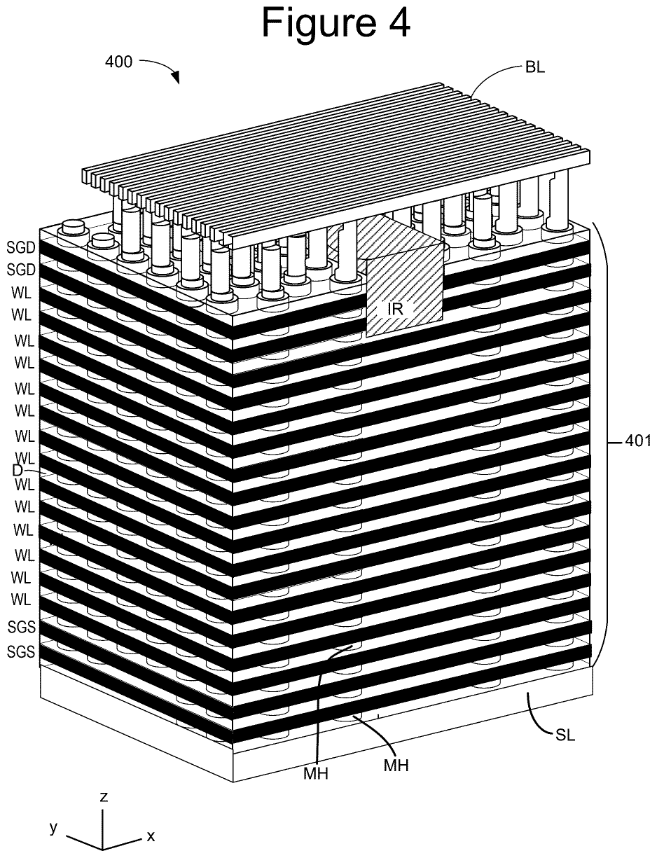

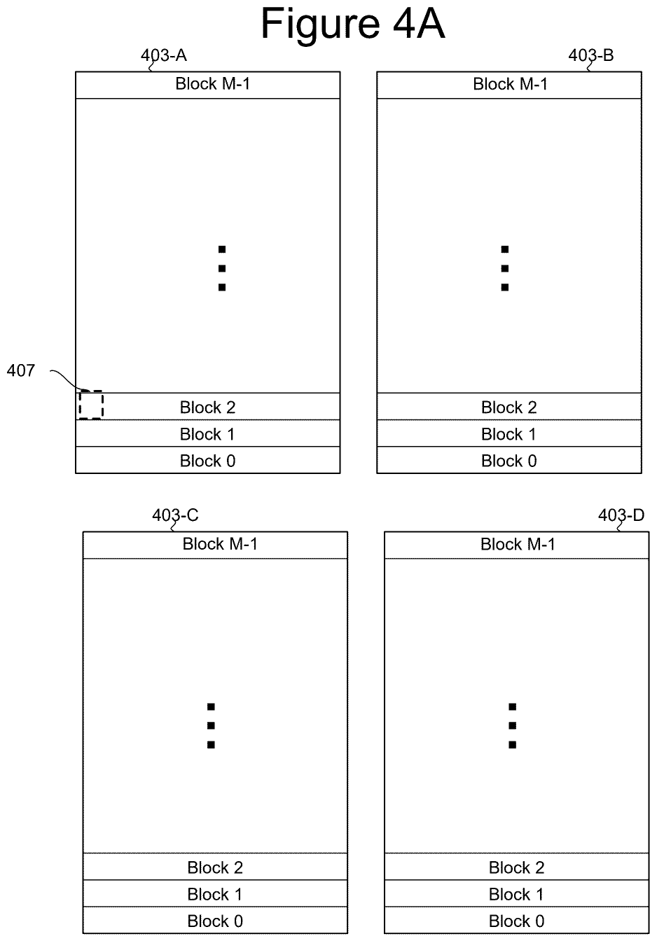

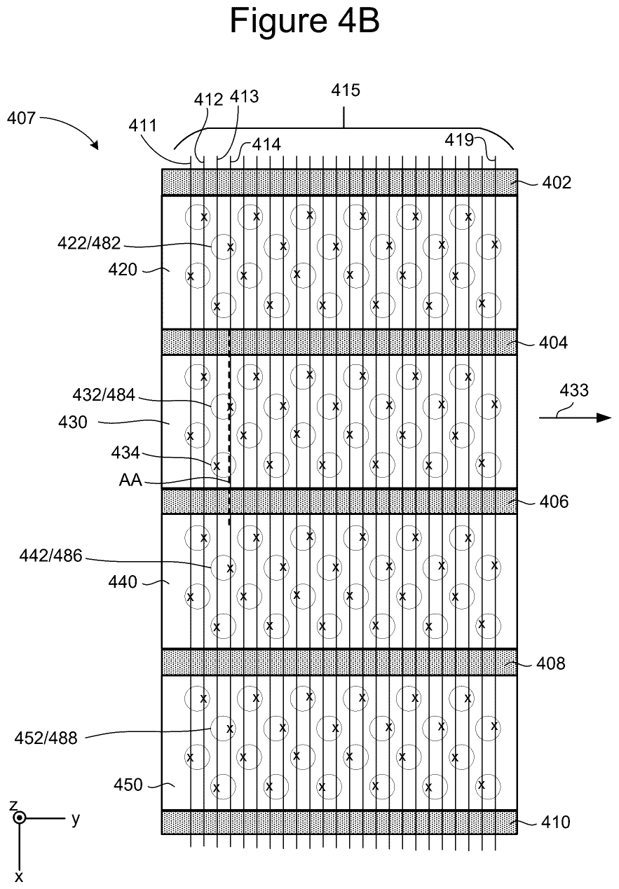

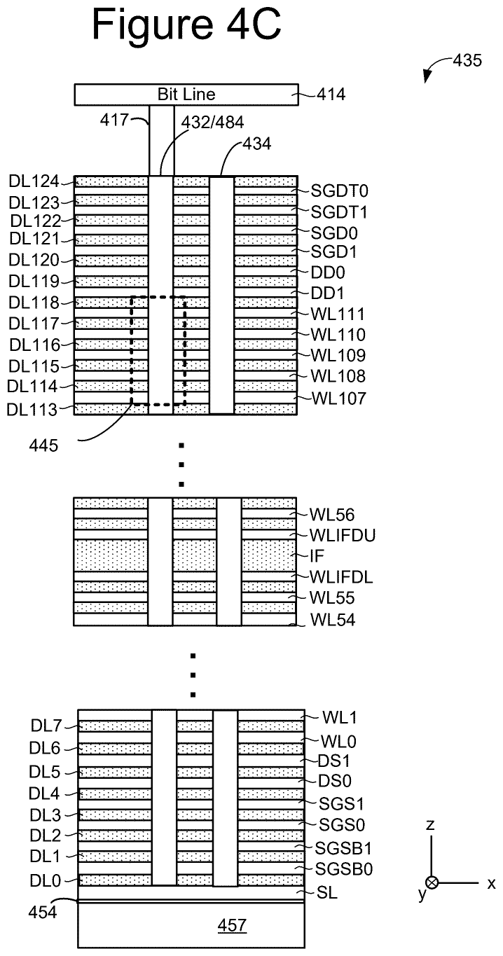

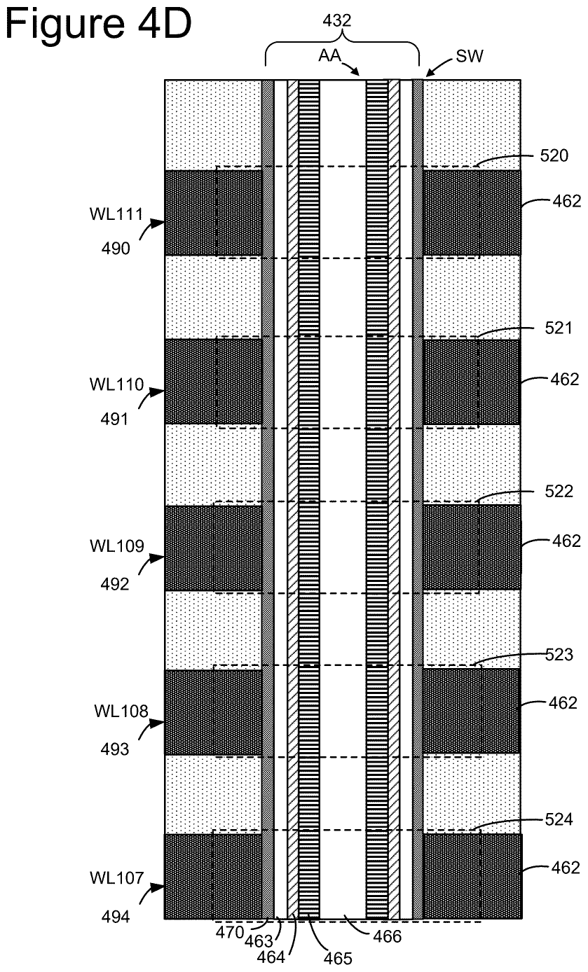

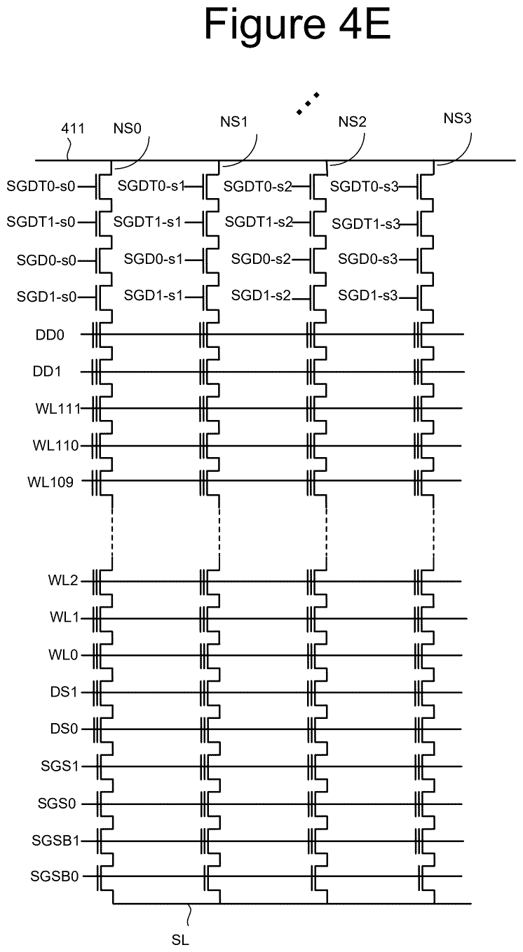

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2B onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more dies, such as two memory dies and one control die, for example.

FIG. 2C shows an alternative arrangement to that of FIG. 2B which may be implemented using wafer-to-wafer bonding to provide a bonded die pair. FIG. 2C depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2C shows an example of the peripheral circuitry, including control circuits, formed in a peripheral circuit or control die 211 coupled to memory structure 202 formed in memory structure die 201. Common components are labelled similarly to FIG. 2B. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201. The memory structure die 201 includes a temperature sensor 258, which is configured to sense temperature on the memory structure die 201 and report the temperature to the system control logic 260. In an embodiment, the temperature sensor 258 is used to sense temperature during a recovery of memory cells that uses self-heating. The location of the temperature sensor 258 is not limited to a particular area of the memory structure die 201. Thus, it will be understood that the location of the temperature sensor 258 is not limited to the region depicted in FIG. 2C. There may be more than one temperature sensors 258 on the memory structure die 201. In an embodiment, the temperature sensor 258 is used to sense temperature during a recovery of memory cells that uses self-heating.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2C shows column control circuitry 210 including read/write circuits 225 on the control die 211 coupled to memory structure 202 on the memory structure die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each electrical path 208 may correspond to a word line, dummy word line, or select gate line. Additional electrical paths may also be provided between control die 211 and memory structure die 201.

For purposes of this document, the phrases “a control circuit” or “one or more control circuits” can include, but is not limited to, any one of or any combination of memory controller 120, all or a portion of system control logic 260, all or a portion of row control circuitry 220, all or a portion of column control circuitry 210, read/write circuits 225, a host external to the storage system, a host external to the storage 130, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit. Note that the host external to the storage system 100 or the host external to the storage 130 might be a host that is used in a test or factory environment in which memory cells in the storage 130 are recovered at the end of life by self-heating using victim NAND strings as described herein.

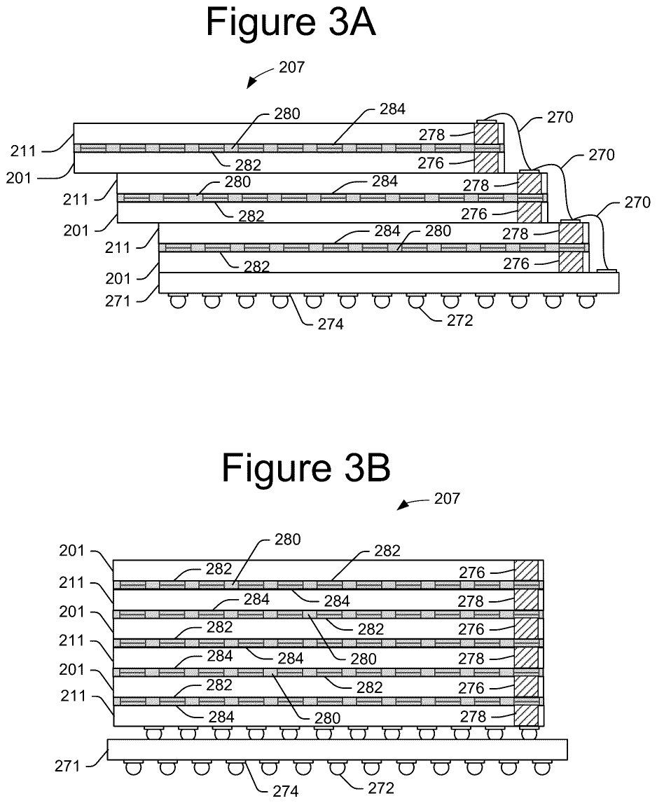

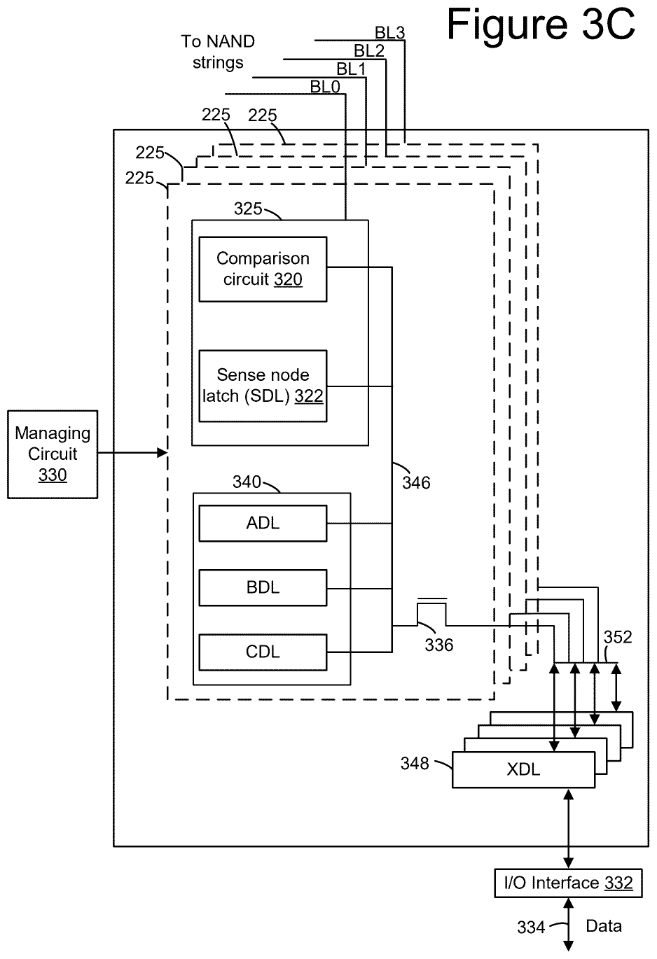

In some embodiments, there is more than one control die 211 and more than one memory structure die 201 in an integrated memory assembly 207. In some embodiments, the integrated memory assembly 207 includes a stack of multiple control dies 211 and multiple memory structure dies 201. FIG. 3A depicts a side view of an embodiment of an integrated memory assembly 207 stacked on a substrate 271 (e.g., a stack comprising control die 211 and memory structure die). The integrated memory assembly 207 has three control dies 211 and three memory structure dies 201. In some embodiments, there are more than three memory structure dies 201 and more than three control dies 211. In FIG. 3A there are an equal number of memory structure dies 201 and control dies 211; however, in one embodiment, there are more memory structure dies 201 than control dies 211. For example, one control die 211 could control multiple memory structure dies 201.

Each control die 211 is affixed (e.g., bonded) to at least one of the memory structure die 201. Some of the bond pads 282/284 are depicted. There may be many more bond pads. A space between two die 201, 211 that are bonded together is filled with a solid layer 280, which may be formed from epoxy or other resin or polymer. This solid layer 280 protects the electrical connections between the die 201, 211, and further secures the die together. Various materials may be used as solid layer 280.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory structure die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 211 and three memory structure dies 201. In some embodiments, there are many more than three memory structure dies 201 and many more than three control dies 211. In this example, each control die 211 is bonded to at least one memory structure die 201. Optionally, a control die 211 may be bonded to two or more memory structure dies 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory structure die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory structure die 201 may be bonded together. Bond pads on each die 201, 211 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the die may be under filled with an epoxy or other resin or polymer. The under-fill material may be applied as a liquid which then hardens into a solid layer. This under-fill step protects the electrical connections between the dies 201, 211, and further secures the die together. Various materials may be used as under-fill material.

FIG. 3C is a block diagram depicting one embodiment of a portion of column control circuitry 210 that contains a number of read/write circuits 225. Each read/write circuit 225 is partitioned into a sense amplifier 325 and data latches 340. A managing circuit 330 controls the read/write circuits 225. The managing circuit 330 may communicate with state machine 262. In one embodiment, each sense amplifier 325 is connected to a respective bit line. Each bit line may be connected, at one point in time, to one of a large number of different NAND strings. A select gate on the NAND string may be used to connect the NAND string channel to the bit line.

Each sense amplifier 325 operates to provide voltages to one of the bit lines (see BL0, BL1, BL2, BL3) during program, verify, erase, and read operations. Sense amplifiers are also used to sense the condition (e.g., data state) of a memory cell in a NAND string connected to the bit line that connects to the respective sense amplifier.

Each sense amplifier 325 may have a sense node. During sensing, a sense node (SEN) is charged up to an initial voltage, Vsense_init, such as 3V. The sense node is then connected to the bit line for a sensing time, and an amount of decay of the sense node is used to determine whether a memory cell is in a conductive or non-conductive state. The amount of decay of the sense node also indicates whether a current Icell in the memory cell exceeds a reference current, Iref. A larger decay corresponds to a larger current. If Icell<=Iref, the memory cell is in a non-conductive state and if Icell>Iref, the memory cell is in a conductive state. In an embodiment, the sense node has a capacitor that is pre-charged and then discharged for the sensing time.

In particular, the comparison circuit 320 determines the amount of decay by comparing the sense node voltage to a trip voltage after the sensing time. If the sense node voltage decays below the trip voltage, Vtrip, the memory cell is in a conductive state and its Vth is at or below the verify voltage. If the sense node voltage does not decay below Vtrip, the memory cell is in a non-conductive state and its Vth is above the program verify voltage. A sense node latch (SDL) 322 is set to 0 or 1, for example, by the comparison circuit 320 based on whether the memory cell is in a conductive or non-conductive state, respectively. The bit in the sense node latch 322 can also be used in a lockout scan to decide whether to set a bit line voltage to an inhibit or a program enable level in a next program loop. The bit in the sense node latch 322 can also be used in a lockout mode to decide whether to set a bit line voltage to a sense voltage or a lockout voltage in a read operation. The sense node latch 322 may also be referred to herein as “SDL”.

The data latches 340 are coupled to the sense amplifier 325 by a local data bus 346. The data latches 340 include three latches (ADL, BDL, CDL) for each sense amplifier 325 in this example. More or fewer than three latches may be included in the data latches 340. In one embodiment, for programming each data latch 340 is used to store one bit to be stored into a memory cell and for reading each data latch 340 is used to store one bit read from a memory cell. In a three bit per memory cell embodiment, ADL stores a bit for a lower page of data, BDL stores a bit for a middle page of data, CDL stores a bit for an upper page of data. Each read/write circuit 225 is connected to an XDL latch 348 by way of an XDL bus 352. In this example, transistor 336 connects local data bus 346 to XDL bus 352. An I/O interface 332 is connected to the XDL latches 348. The XDL latch 348 associated with a particular read/write circuit 225 serves as an interface latch for storing/latching data from the memory controller.

Managing circuit 330 performs computations, such as to determine the data stored in the sensed memory cell and store the determined data in the set of data latches. Each set of data latches 340 is used to store data bits determined by managing circuit 330 during a read operation, and to store data bits imported from the data bus 334 during a program operation which represent write data meant to be programmed into the memory. I/O interface 332 provides an interface between XDL latches 348 and the data bus 334.

During reading, the operation of the system is under the control of state machine 262 that controls the supply of different control gate voltages to the addressed memory cell. As it steps through the various predefined control gate voltages corresponding to the various memory states supported by the memory, the sense circuit may trip at one of these voltages and a corresponding output will be provided from the sense amplifier to managing circuit 330. At that point, managing circuit 330 determines the resultant memory state by consideration of the tripping event(s) of the sense circuit and the information about the applied control gate voltage from the state machine. It then computes a binary encoding for the memory state and stores the resultant data bits into data latches 340.

During program or verify operations for memory cells, the data to be programmed (write data) is stored in the set of data latches 340 from the data bus 334 by way of XDL latches 348. The program operation, under the control of the state machine 262, applies a series of programming voltage pulses to the control gates of the addressed memory cells. Each voltage pulse may be stepped up in magnitude from a previous program pulse by a step size in a process referred to as incremental step pulse programming. In one embodiment, each program voltage is followed by a verify operation to determine if the memory cells have been programmed to the desired memory state. In some cases, managing circuit 330 monitors the read back memory state relative to the desired memory state. When the two agree, managing circuit 330 sets the bit line in a program inhibit mode such as by updating its latches. This inhibits the memory cell coupled to the bit line from further programming even if additional program pulses are applied to its control gate.

FIG. 4 is a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D. The conductive layers are labeled as one of: SGD, WL, or SGS. An SGD conductive layer serves as drain side select lines. A WL conductive layer serves as a word line. An SGS conductive layer serves as a source side select line. The numbers of each of these conductive layers is limited for ease of illustration. The number of alternating dielectric layers and conductive layers can vary based on specific implementation requirements. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

In one embodiment the block is operated as a number of “sub-blocks.” Each of these “sub-blocks” has many NAND strings. In an embodiment, an isolation region (IR) divides the SGD layers into multiple SGD select lines, each of which is used to select a sub-block (e.g., set of NAND strings). FIG. 4 depicts an example having one IR region and thereby two sub-blocks. However, there may be more than one IR region and thereby more than two sub-blocks. Optionally, the IR region can extend down through all of the alternating dielectric layers and conductive layers.

FIG. 4A is a block diagram explaining one example organization of memory structure 202, which is divided into four planes 403-A, 403-B, 403-C, 403-D. Each plane is then divided into M physical blocks. In one example, each plane has about 2000 physical blocks (or more briefly “blocks”). However, different numbers of blocks and planes can also be used. In one “full-block” embodiment, a block of memory cells is a unit of erase. That is, all memory cells of a block are erased together. In a “sub-block mode” embodiment, blocks are divided into sub-blocks and the sub-blocks are the unit of erase. In an embodiment, a block contains a number of word lines with each sub-block containing a unique set of the data word lines. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows four planes 403 more or fewer than four planes can be implemented. In some embodiments, memory structure 202 is an extreme multi-plane architecture with, for example, 32, 64, 128 or some other large number of planes. In some embodiments, programming and reading can be performed in parallel in a selected block in each plane 403.

FIGS. 4B-4E depict an example three dimensional (“3D”) NAND structure that corresponds to the structure of FIG. 4 and can be used to implement memory structure 202 of FIGS. 2B and 2C. FIG. 4B is a diagram depicting a top view of a portion 407 of Block 2. As can be seen from FIG. 4B, the physical block depicted in FIG. 4B extends in the direction of arrow 433. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442, and 452. Vertical column 422 implements NAND string 482. Vertical column 432 implements NAND string 484. Vertical column 442 implements NAND string 486. Vertical column 452 implements NAND string 488. More details of the vertical columns are provided below. Since the physical block depicted in FIG. 4B extends in the direction of arrow 433, the physical block includes more vertical columns than depicted in FIG. 4B.

FIG. 4B also depicts a set of bit lines 415, including bit lines 411, 412, 413, 414, ... 419. FIG. 4B shows twenty-four bit lines because only a portion of the physical block is depicted. It is contemplated that more than twenty-four bit lines connected to vertical columns of the physical block. Each of the circles representing vertical columns has an “x” to indicate its connection to one bit line. For example, bit line 414 is connected to vertical columns 422, 432, 442 and 452.

The physical block depicted in FIG. 4B includes a set of isolation regions 402, 404, 406, 408, and 410, which are formed of SiO₂; however, other dielectric materials can also be used. Isolation regions 402, 404, 406, 408, and 410 serve to divide the top layers of the physical block into four regions; for example, the top layer depicted in FIG. 4B is divided into regions 420, 430, 440, and 450, which are referred to herein as “sub-blocks. Each sub-block contains a large number of NAND strings. In one embodiment, isolation regions 402 and 410 separate the physical block 407 from adjacent physical blocks. Thus, isolation regions 402 and 410 may extend down to the substrate. In one embodiment, the isolation regions 404, 406, and 408 only divide the layers used to implement select gates so that NAND strings in different strings can be independently selected. Referring back to FIG. 4, the IR region may correspond to any of isolation regions 404, 406, or 408. In one example implementation, a bit line only connects to one vertical column/NAND string in each of regions (sub-blocks) 420, 430, 440, and 450. In that implementation, each physical block has sixteen rows of active columns and each bit line connects to four NAND strings in each block. In one embodiment, all of the four vertical columns/NAND strings connected to a common bit line are connected to the same word line (or set of word lines); therefore, the system uses the drain side selection lines to choose one (or another subset) of the four to be subjected to a memory operation (program, verify, read, and/or erase).

Although FIG. 4B shows each region (420, 430, 440, 450) having four rows of vertical columns, four regions (420, 430, 440, 450) and sixteen rows of vertical columns in a block, those exact numbers are an example implementation. Other embodiments may include more or fewer regions (420, 430, 440, 450) per block, more or fewer rows of vertical columns per region and more or fewer rows of vertical columns per block. FIG. 4B also shows the vertical columns being staggered. In other embodiments, different patterns of staggering can be used. In some embodiments, the vertical columns are not staggered.

FIG. 4C depicts an example of a stack 435 showing a cross-sectional view along line AA of FIG. 4B. The SGD layers include SGDT0, SGDT1, SGD0, and SGD1. The SGD layers may have more or fewer than four layers. The SGS layers includes SGSB0, SGSB1, SGS0, and SGS1. The SGS layers may have more or fewer than four layers. Six dummy word line layers DD0, DD1, WLIFDU, WLIFDL, DS1, and DS0 are provided, in addition to the data word line layers WL0-WL111. There may be more or fewer than 112 data word line layers and more or fewer than four dummy word line layers. Each NAND string has a drain side select gate at the SGD layers. Each NAND string has a source side select gate at the SGS layers. Also depicted are dielectric layers DL0-DL124.

Columns 432, 434 of memory cells are depicted in the multi-layer stack. The stack includes a substrate 457, an insulating film 454 on the substrate, and a portion of a source line SL. A portion of the bit line 414 is also depicted. Note that NAND string 484 is connected to the bit line 414. NAND string 484 has a source-end at a bottom of the stack and a drain-end at a top of the stack. The source-end is connected to the source line SL. A conductive via 417 connects the drain-end of NAND string 484 to the bit line 414.

In one embodiment, the memory cells are arranged in NAND strings. The word line layers WL0-WL111 connect to memory cells (also called data memory cells). Dummy word line layers DD0, DD1, DS0 and DS1 connect to dummy memory cells. A dummy memory cell does not store and is not eligible to store host data (data provided from the host, such as data from a user of the host), while a data memory cell is eligible to store host data. In some embodiments, data memory cells and dummy memory cells may have the same structure. Drain side select layers SGD are used to electrically connect and disconnect (or cut off) the channels of respective NAND strings from bit lines. Source side select layers SGS are used to electrically connect and disconnect (or cut off) the channels of respective NAND strings from the source line SL.

FIG. 4C depicts an example of a stack 435 having two sub-blocks (SB). A two SB or other multi-SB stack can be used to form a relatively tall stack while maintaining a relatively narrow memory hole width (or diameter). After the layers of the lower SB are formed, memory hole portions are formed in the lower SB. Subsequently, after the layers of the upper SB are formed, memory hole portions are formed in the upper SB, aligned with the memory hole portions in the lower SB to form continuous memory holes from the bottom to the top of the stack. The resulting memory hole is narrower than would be the case if the hole were etched from the top to the bottom of the stack rather than in each SB individually. An interface (IF) region is created where the two SBs are connected. The IF region is typically thicker than the other dielectric layers. Due to the presence of the IF region, the adjacent word line layers suffer from edge effects such as difficulty in programming or erasing. These adjacent word line layers can therefore be set as dummy word lines (WLIFDL, WLIFDU).

FIG. 4D depicts a view of the region 445 of FIG. 4C. Data memory cell transistors 520, 521, 522, 523, and 524 are indicated by the dashed lines. A number of layers can be deposited along the sidewall (SW) of the memory hole 432 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel.

Each of the memory holes can be filled with a plurality of annular layers (also referred to as memory film layers) comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration.

FIG. 4E is a schematic diagram of a portion of the memory array 202. FIG. 4E shows physical data word lines WL0-WL111 running across the entire block. The structure of FIG. 4E corresponds to a portion 407 in Block 2 of FIG. 4A, including bit line 411. Within the physical block, in one embodiment, each bit line is connected to four NAND strings. Thus, FIG. 4E shows bit line 411 connected to NAND string NS0, NAND string NS1, NAND string NS2, and NAND string NS3.

In one embodiment, there are four sets of drain side select lines in the physical block. For example, the set of drain side select lines connected to NS0 include SGDT0-s0, SGDT1-s0, SGD0-s0, and SGD1-s0. The set of drain side select lines connected to NS1 include SGDT0-s1, SGDT1-s1, SGD0-s1, and SGD1-s1. The set of drain side select lines connected to NS2 include SGDT0-s2, SGDT1-s2, SGD0-s2, and SGD1-s2. The set of drain side select lines connected to NS3 include SGDT0-s3, SGDT1-s3, SGD0-s3, and SGD1-s3. Herein the term “SGD” may be used as a general term to refer to any one or more of the lines in a set of drain side select lines. In some embodiments, the same operating voltage is applied to SGDT0 and SGDT1. In some embodiments, the same operating voltage is applied to SGD0 and SGD1. In some erase embodiments, different operating voltage are applied to SGDT0/SGDT1 than to SGD0/SGD1. Note that SGDT0/SGDT1 are adjacent to the bit line. In some erase embodiments, a voltage applied to SGDT0/SGDT1 in combination with a bit line voltage may be used to generate a gate induced gate leakage (GIDL) current. Such a voltage applied to SGDT0/SGDT1 may be referred to herein as a GIDL voltage.

In an embodiment, each line in a given set may be operated independent from the other lines in that set to allow for different voltages to the gates of the four drain side select transistors on the NAND string. Moreover, each set of drain side select lines can be selected independent of the other sets. Each set drain side select lines connects to a group of NAND strings in the block. Only one NAND string of each group is depicted in FIG. 4E. These four sets of drain side select lines correspond to four “sub-blocks.” A first sub-block corresponds to those vertical NAND strings controlled by SGDT0-s0, SGDT1-s0, SGD0-s0, and SGD1-s0. A second sub-block corresponds to those vertical NAND strings controlled by SGDT0-s1, SGDT1-s1, SGD0-s1, and SGD1-s1. A third sub-block corresponds to those vertical NAND strings controlled by SGDT0-s2, SGDT1-s2, SGD0-s2, and SGD1-s2. A fourth sub-block corresponds to those vertical NAND strings controlled by SGDT0-s3, SGDT1-s3, SGD0-s3, and SGD1-s3. As noted, FIG. 4E only shows the NAND strings connected to bit line 411. However, a full schematic of the block would show every bit line and four vertical NAND strings connected to each bit line.

In one embodiment, all of the memory cells on the NAND strings in a physical block are erased as a unit. However, in some embodiments, a physical block is operated as multiple tiers, with each tier containing a contiguous set of word lines. For example, memory cells connected to WL0-WL55 may be in one tier and memory cells connected to WL56-WL111 may be in another tier. A physical block could be operated in more than two tiers. Erase units can be formed based on other divisions of physical blocks.

Although the example memories of FIGS. 4-4E are three dimensional memory structure that includes vertical NAND strings with charge-trapping material, other 3D memory structures can also be used with the technology described herein.

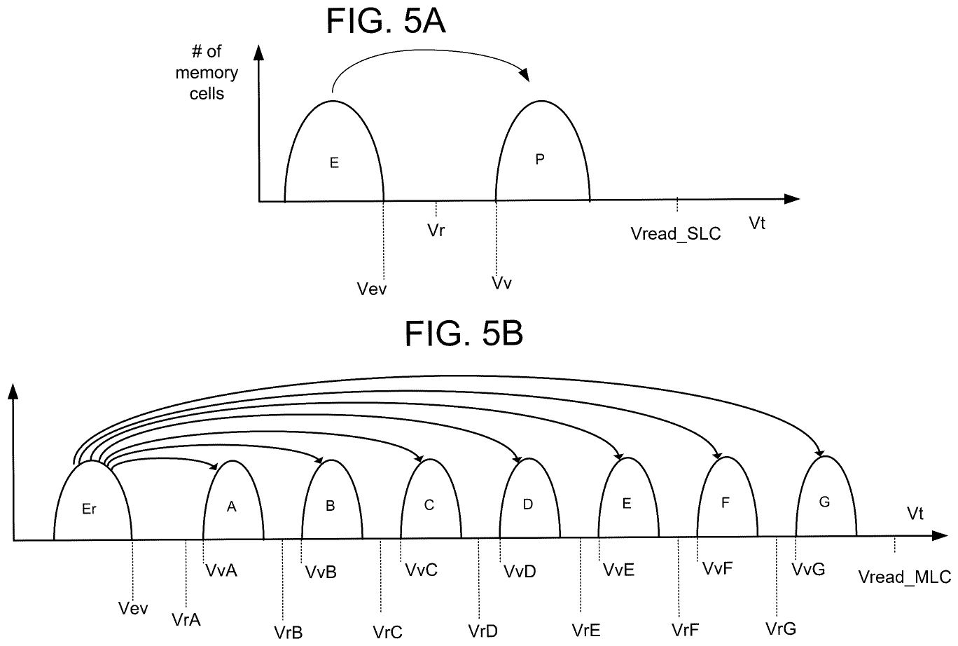

The storage systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, and illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data.

At the end of a successful programming process, the threshold voltages of the memory cells should be within one or more distributions of threshold voltages for programmed memory cells or within a distribution of threshold voltages for erased memory cells, as appropriate. FIG. 5A a graph of threshold voltage versus number of memory cells, and illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read reference voltage Vr. By testing (e.g., performing one or more sense operations) whether the threshold voltage of a given memory cell is above or below Vr, the system can determine whether a memory cell is erased (state E) or programmed (state P). FIG. 5A also depicts verify reference voltage Vv. In some embodiments, when programming memory cells to data state P, the system will test whether those memory cells have a threshold voltage greater than or equal to Vv. FIG. 5A also shows a read pass voltage, which is referred to as Vread_SLC. The magnitude of Vread_SLC is sufficiently great to turn on a memory cell whether it is in the E state or the P state. The read pass voltage may be applied to memory cells on the NAND string that are not selected for a read operation to cause those unselected memory cells to turn on during the read operation. In an embodiment, Vread_SLC is applied to control gates of memory cells on victim NAND strings to generate a large current for self-heating for recovery of NAND at end of life.

Memory cells that store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5B, each memory cell stores three bits of data. Other embodiments may use other data capacities per memory cell (e.g., such as two, four, or five bits of data per memory cell).

FIG. 5B shows eight threshold voltage distributions, corresponding to eight data states. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. In an embodiment, the number of memory cells in each state is about the same.

FIG. 5B shows seven read reference voltages, VrA, VrB, VrC, VrD, VrE, VrF, and VrG for reading data from memory cells. By testing (e.g., performing sense operations) whether the threshold voltage of a given memory cell is above or below the seven read reference voltages, the system can determine what data state (i.e., A, B, C, D, . . . ) a memory cell is in. FIG. 5B also shows a number of verify reference voltages. The verify reference voltages are VvA, VvB, VvC, VvD, VvE, VvF, and VvG. In some embodiments, when programming memory cells to data state A, the system will test whether those memory cells have a threshold voltage greater than or equal to VvA. If the memory cell has a threshold voltage greater than or equal to VvA, then the memory cell is locked out from further programming. Similar reasoning applies to the other data states.

FIG. 5B also shows a read pass voltage, which is referred to as Vread_MLC. The magnitude of Vread_MLC is sufficiently great to turn on a memory cell in any of the Vt distributions. The read pass voltage may be applied to memory cells on the NAND string that are not selected for a read operation to cause those unselected memory cells to turn on during the read operation. In an embodiment, Vread_MLC is applied to control gates of memory cells on victim NAND strings to generate a large current for self-heating for recovery of NAND at end of life.

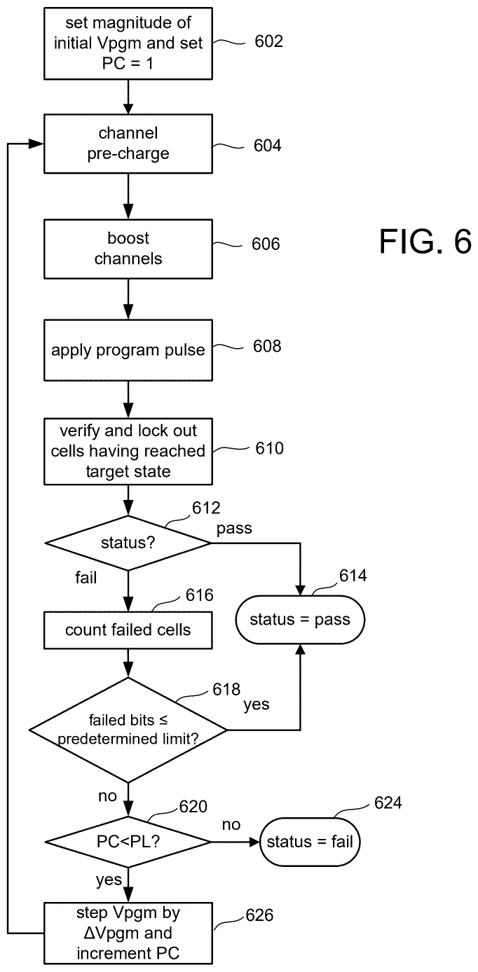

FIG. 6 is a flowchart describing one embodiment of a process for programming memory cells. For purposes of this document, the term program and programming are synonymous with write and writing. In one example embodiment, the process of FIG. 6 is performed for memory structure 202 using the one or more control circuits (e.g., system control logic 260, column control circuitry 210, row control circuitry 220) discussed above. In one example embodiment, the process of FIG. 6 is performed by integrated memory assembly 207 using the one or more control circuits (e.g., system control logic 260, column control circuitry 210, row control circuitry 220) of control die 211 to program memory cells on memory structure die 201. The process includes multiple loops, each of which includes a program phase and a verify phase. The process of FIG. 6 is performed to implement the full sequence programming, as well as other programming schemes including multi-stage programming. When implementing multi-stage programming, the process of FIG. 6 is used to implement any/each stage of the multi-stage programming process.

Typically, the program voltage applied to the control gates (via a selected data word line) during a program operation is applied as a series of program pulses (e.g., voltage pulses). Between programming pulses a set of verify pulses (e.g., voltage pulses) may be used to perform verification. In many implementations, the magnitude of the program pulses is increased with each successive pulse by a predetermined step size. In step 602 of FIG. 6, the programming voltage signal (Vpgm) is initialized to the starting magnitude (e.g., ~12-16V or another suitable level) and a program counter PC maintained by state machine 262 is initialized at 1. In one embodiment, the group of memory cells selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming. Additionally, as memory cells reach their intended target data state, they will be inhibited from further programming. Those NAND strings (e.g., unselected NAND strings) that include memory cells connected to the selected word line that are to be inhibited from programming have their channels boosted to inhibit programming. When a channel has a boosted voltage, the voltage differential between the channel and the word line is not large enough to cause programming. To assist in the boosting, in step 604 the control die will pre-charge channels of NAND strings that include memory cells connected to the selected word line that are to be inhibited from programming. In step 606, NAND strings that include memory cells connected to the selected word line that are to be inhibited from programming have their channels boosted to inhibit programming. Such NAND strings are referred to herein as “unselected NAND strings.” In one embodiment, the unselected word lines receive one or more boosting voltages (e.g., ~7-11 volts) to perform boosting schemes. A program inhibit voltage is applied to the bit lines coupled the unselected NAND string.

In step 608, a program voltage pulse of the programming voltage signal Vpgm is applied to the selected word line (the word line selected for programming). If a memory cell on a NAND string should be programmed, then the corresponding bit line is biased at a program enable voltage. In step 608, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all of the memory cells connected to the selected word line will concurrently have their threshold voltage change, unless they are inhibited from programming.

In step 610, program verify is performed and memory cells that have reached their target states are locked out from further programming by the control die. Step 610 includes performing verification of programming by sensing at one or more verify reference levels. In one embodiment, the verification process is performed by testing whether the threshold voltages of the memory cells selected for programming have reached the appropriate verify reference voltage. In step 610, a memory cell may be locked out after the memory cell has been verified (by a test of the Vt) that the memory cell has reached its target state. For example, a memory cell may be locked out if it reaches a verify reference voltage.

If, in step 612, it is determined that all of the memory cells have reached their target threshold voltages (pass), the programming process is complete and successful because all selected memory cells were programmed and verified to their target states. A status of “PASS” is reported in step 614. Otherwise if, in step 612, it is determined that not all of the memory cells have reached their target threshold voltages (fail), then the programming process continues to step 616.

In step 616, the number of memory cells that have not yet reached their respective target threshold voltage distribution are counted. That is, the number of memory cells that have, so far, failed to reach their target state are counted. This counting can be done by state machine 262, memory controller 120, or another circuit. In one embodiment, there is one total count, which reflects the total number of memory cells currently being programmed that have failed the last verify step. In another embodiment, separate counts are kept for each data state.

In step 618, it is determined whether the count from step 616 is less than or equal to a predetermined limit. In one embodiment, the predetermined limit is the number of bits that can be corrected by error correction codes (ECC) during a read process for the page of memory cells. If the number of failed cells is less than or equal to the predetermined limit, than the programming process can stop and a status of “PASS” is reported in step 614. In this situation, enough memory cells programmed correctly such that the few remaining memory cells that have not been completely programmed can be corrected using ECC during the read process. In some embodiments, the predetermined limit used in step 618 is below the number of bits that can be corrected by error correction codes (ECC) during a read process to allow for future/additional errors. When programming fewer than all of the memory cells for a page, or comparing a count for only one data state (or less than all states), than the predetermined limit can be a portion (pro-rata or not pro-rata) of the number of bits that can be corrected by ECC during a read process for the page of memory cells. In some embodiments, the limit is not predetermined. Instead, it changes based on the number of errors already counted for the page, the number of program-erase cycles performed or other criteria.

If the number of failed memory cells is not less than the predetermined limit, then the programming process continues at step 620 and the program counter PC is checked against the program limit value (PL). Examples of program limit values include 6, 12, 16, 19, 20 and 30; however, other values can be used. If the program counter PC is not less than the program limit value PL, then the program process is considered to have failed and a status of FAIL is reported in step 624. If the program counter PC is less than the program limit value PL, then the process continues at step 626 during which time the Program Counter PC is incremented by 1 and the programming voltage signal Vpgm is stepped up to the next magnitude. For example, the next pulse will have a magnitude greater than the previous pulse by a step size ΔVpgm (e.g., a step size of 0.1-1.0 volts). After step 626, the process loops back to step 604 and another program pulse is applied to the selected word line so that another iteration (steps 604-626) of the programming process of FIG. 6 is performed.

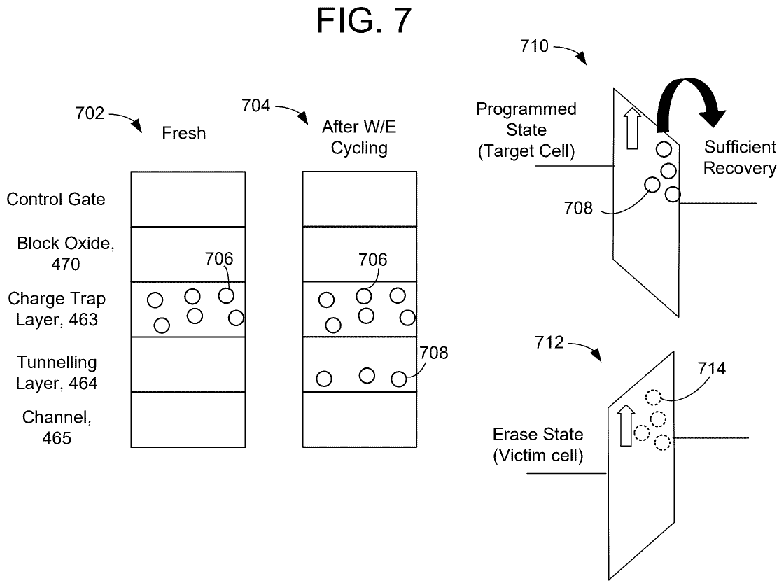

FIG. 7 depicts how trapped electrons in a target cell may be removed, in an embodiment, by using a victim cell to heat the target cell. The various layers of a memory cell are depicted in blocks 702 and 704. Block 702 shows the memory cell in a fresh condition in which charges 706 have been stored in the charge trap layer 463 as a result of programming the memory cell. Note that to program the memory cells, the charges 706 tunnel through the tunneling layer 464. When the memory cell is erased, the charges 706 that are removed from the charge trap layer 483 again pass through the tunneling layer 464 to the channel 465. There is a small, but non-zero, probability that a charge 706 will become trapped in the tunneling layer 464 during a program or erase. The tunneling layer 464 is free from trapped charges when the memory cell is fresh. Block 704 shows the memory cell after a significant number of write/erase (W/E) cycles in which there are now trapped charges 708 in the tunneling layer 464. Such trapped charges 708 impair the operation of the memory cell and could cause the cell to be a fail bit.

FIG. 7 also depicts an energy band diagram 710 for a target cell during the thermal recovery. The target cell is in a programmed state during an embodiment of the thermal recovery. Being in the programmed state during the thermal recovery provides a lower barrier for the trapped charges 708 to thereby make it easier for the trapped charges 708 to leave the tunneling layer 464.

FIG. 7 also depicts an energy band diagram 712 for a victim cell during the thermal recovery. The victim cell is in an erase state during an embodiment of the thermal recovery. Being in the erased state helps the victim cell generate a larger current and thereby a larger amount of heating. Note that the victim cell could be selected from a set of redundant cells that are only used for data storage if there is a need to replace a regular memory cell. Thus, the victim cell does not need to be programmed repeatedly. Therefore, the victim cell does not necessarily have trapped charges. However, hypothetical trapped charges 714 are depicted in the victim cell for purpose of illustration of the higher barrier that such trapped charges 714 face relative to the programmed target cell. Thus, if a target cell were in the erased state instead of the programmed state the recovery may be suppressed because the trapped electrons would need a higher energy to overcome the barrier.

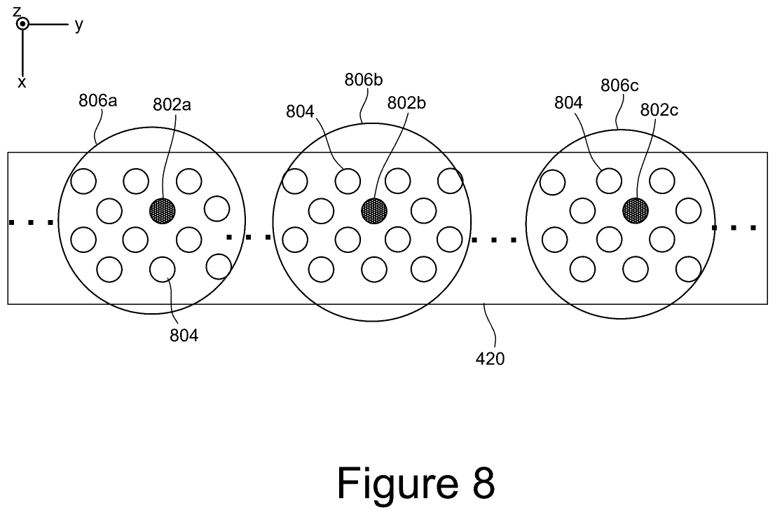

FIG. 8 depicts a top view of a sub-block of NAND memory cells to illustrate principles of an embodiment of self-heating NAND using victim cells. The term “victim cell” refers to a memory cell on a “victim ANND string.” FIG. 8 shows a top view of sub-block 420 that was depicted FIG. 4B, but without the bit lines. Note that FIG. 8 shows just one of the sub-blocks 420 in the block. Also, FIG. 8 shows a top view of just a few of the NAND string in the sub-block. There may be thousands of NAND strings in a sub-block 420.

One or more victim NAND strings 802 are selected. In this example, three victim NAND strings 802a, 802b, 802c have been selected. However, as few as a single victim NAND string 802 could be selected. Also, more than three victim NAND strings 802 could be selected. Each victim NAND string 802 heats are region near the victim NAND string 802. In this simplified example, victim NAND string 802a heats at least region 806a, victim NAND string 802b heats at least region 806b, and victim NAND string 802c heats at least region 806c. Several of the target NAND strings 804 are pointed out. The target NAND strings 804 will be heated by the victim NAND strings 802 to thereby remove trapped charges in the memory cells of the target NAND strings 802. The heating may extend to a far greater extent than depicted in FIG. 8. Thus, a single victim NAND string 802 may be used to heat many more target NAND strings 804 than are depicted in FIG. 8. Also, there may be overlap between the heating provided by the victim NAND strings 802.

As an example the sub-block 420 might extend for about 50 micrometers in the y-direction. The victim NAND strings 802 may be spread across the sub-block 420 to provide for even heating. FIG. 8 shows only sub-block 420 having victim NAND strings. The other sub-blocks (see, for example, sub-blocks 430, 440, and 450 in FIG. 4B) may also have victim NAND strings. Also, a victim NAND string 802 may provide heating to target NAND string outside of its sub-block and even outside of its block. For example, sub-blocks 430, 440 and 450 may also contain target NAND strings that are heated by the victim NAND strings 802 in sub-block 420.

In an embodiment, the locations of the victim NAND strings 802 is selected to provide for even heating. FIG. 8 depicts one possible technique in which the locations of victim NAND strings 802 is spread across the sub-block 420. In this example, there is a victim NAND 802 near each end of the sub-block 420 and one victim NAND 802 in the middle of the sub-block 420. Another example is to select just one victim NAND 802 in about the middle of the sub-block 420 (i.e., about midway along the y-axis.). Still another option is to select more than three victim NAND strings 802 in sub-block 420. Also note that other sub-blocks and blocks may also have victim NAND strings selected at the same time.

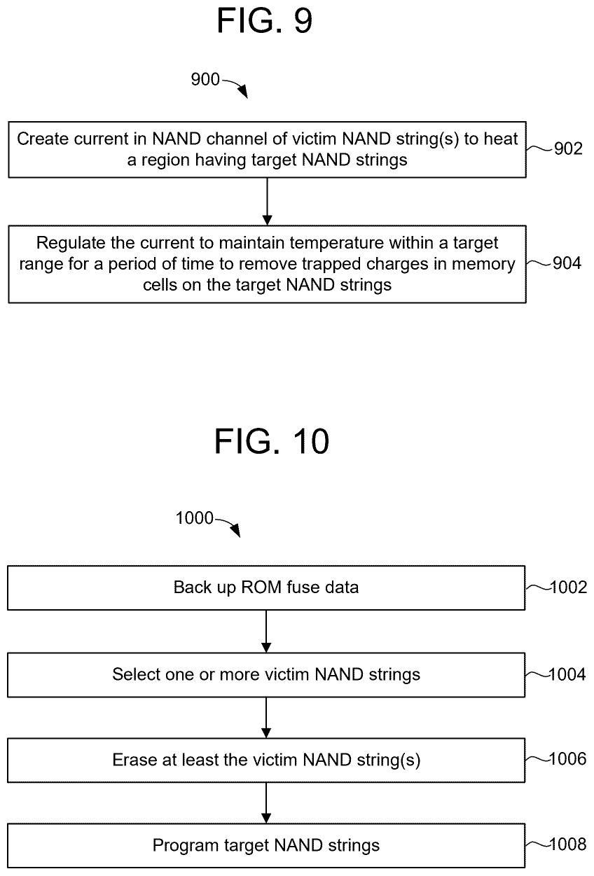

FIG. 9 is a flowchart of one embodiment of a process 900 of self-heating NAND using victim NAND strings to remove trapped charges in the memory cells of target NAND strings. Process 900 may be performed when the NAND memory is at or near its end of life. Process 900 may be performed in a controlled setting on NAND memory devices that have been used by consumers and returned to, for example, the manufacturer or other entity Optionally, process 900 may be performed in-the field in which case the consumer can extend the life of their storage device without the need to return it. Note that prior to performing process 900 there may be some preliminary actions such as backing up information and establishing Vts of memory cells as described in, for example, FIG. 10. In an embodiment, the memory controller 120 in the storage system 100 initiates process 900. In an embodiment, a host external to the storage system initiates process 900. In an embodiment, the memory controller 120 is not involved at all in process 900. For example, host external to storage 130 may initiate process 900.

Process 900 may be performed to recover NAND memory cells in a memory structure 202 that resides on die (e.g., memory die 200, memory structure die 202). The process 900 may be performed once to self-heat and thus recover all of the NAND memory cells on the die. Alternatively, the process 900 may be performed a number of times to self-heat different regions containing different target NAND strings, wherein different groups of target NAND strings are received each time the process 900 is performed.

Step 902 of process 900 includes creating a current in the NAND channel of each of one or more victim NAND strings 802 in the memory structure 202 to heat a region of the memory structure 202 having target NAND strings 804. Techniques and systems for creating the current are discussed below. In some embodiments, the memory cells on the victim NAND string(s) are in the erased state and an overdrive voltage (e.g., Vread) is applied to the control gate in step 902 to provide for a high current and therefore significant heating effect. Step 902 may include applying a voltage to a bit line connected to a victim NAND string while applying a voltage (e.g., Vread) to control gates of the memory cells on the victim NAND string to create the current through the NAND channel of the one or more victim NAND strings.

Step 904 includes regulating the current flow in the victim NAND strings 802 to maintain the temperature within a target range for a period of time to remove trapped charges from memory cells of the target NAND strings 804. Step 904 may include controlling the magnitude of the voltage to the bit line connected to the victim NAND string responsive to the temperature of, for example, the memory structure to regulate the current through the NAND channel of the victim NAND string to maintain the temperature of the memory structure to the target range of temperatures. The period of time for which the temperature is maintained to remove trapped charges may be determined based on factors such as the number of write/erase cycles the NAND memory cells have undergone, the target range of temperatures, and the desired recovery percentage (see FIG. 1). The number of write/erase cycles the NAND memory cells have undergone may be tracked during use of the storage system by, for example, the memory controller 120. The number of write/erase cycles may be stored in the NAND memory itself. The number of write/erase cycles could be maintained for each block in the NAND or some other level of granularity. Even with wear-leveling some blocks may have a significantly higher number of write/erase cycles than others, in which case a worst case write/erase cycles might be used. The target range of temperatures may be based on practical factors such as a need to not exceed a temperature that could damage the storage device, such as a solder reflow temperature. Thus, once a practical temperature range is selected, the number of write/erase cycles is obtained (possibly worst case), and the desired recovery percentage is established, the period of time to maintain the temperature may be determined. string to maintain the temperature of the region to the target range of temperatures.

FIG. 10 is a flowchart of one embodiment of a process 1000 of setting up conditions of the NAND strings prior to self-heating NAND for recovery. The process 1000 may be performed prior to process 900. Process 1000 may be performed in a controlled setting on NAND memory devices that have been used by consumers. Optionally, process 1000 may be performed in-the field. For example, the memory controller 120 in the storage system 100 may oversee process 1000.

Step 1002 includes backing up ROM fuse data. In an embodiment, the ROM fuse data is stored in NAND memory cells in memory structure 202 during the lifetime of the storage 130. The ROM fuse data contains parameters for memory operations. The ROM fuse data could be backed up from the NAND memory cells to the memory controller 120 or another location external to the memory structure 202.

Step 1004 includes selecting one or more victim NAND strings, which will be used for self-heating. In an embodiment, the victim NAND string(s) are selected from the column redundancy bits. In an embodiment, if the storage system 100 detects a bad NAND string (e.g., open or short), it will mark that NAND string as ineligible to store data. Moreover, several nearby NAND strings that are still in good condition will not be used to store data. For example, the storage system 100 may remove a set of eight NAND strings, with the set including the bad NAND string. The system 100 may then select one of the good NAND strings from these “column redundancy bits” for use as a victim NAND string.

Step 1006 includes erasing at least the victim NAND string(s). This erase could erase some, or all, of the target NAND strings as well. Erasing the victim NAND string(s) establishes a low threshold voltage for the memory cells on the victim NAND string(s), which helps to achieve a high memory cell current for the victim NAND strings even with relatively low voltage (e.g., 8V or less) on the control gates. Therefore, the victim NAND strings are able to generate relatively high currents and therefore sufficient heat for recovery of the target NAND strings.

Step 1008 includes programming the target NAND strings. The phrase “programming the target NAND strings” or the like means to program the memory cells to be recovered on the target NAND strings. The target NAND strings may be programmed with a technique such as in FIG. 6, although a different programming technique may be used. With reference to FIG. 7, the memory cells are programmed to reduce the barrier height to facilitate sufficient recovery. As an example, the memory cells could be programmed to approximately a Vt in the range of the C-state distribution or the D-state distribution (see FIG. 5B). However, the memory cells could be programmed to a higher or lower Vt than this example. The precise threshold voltage to which the memory cells are programmed is not critical, hence it is possible to omit program verify.

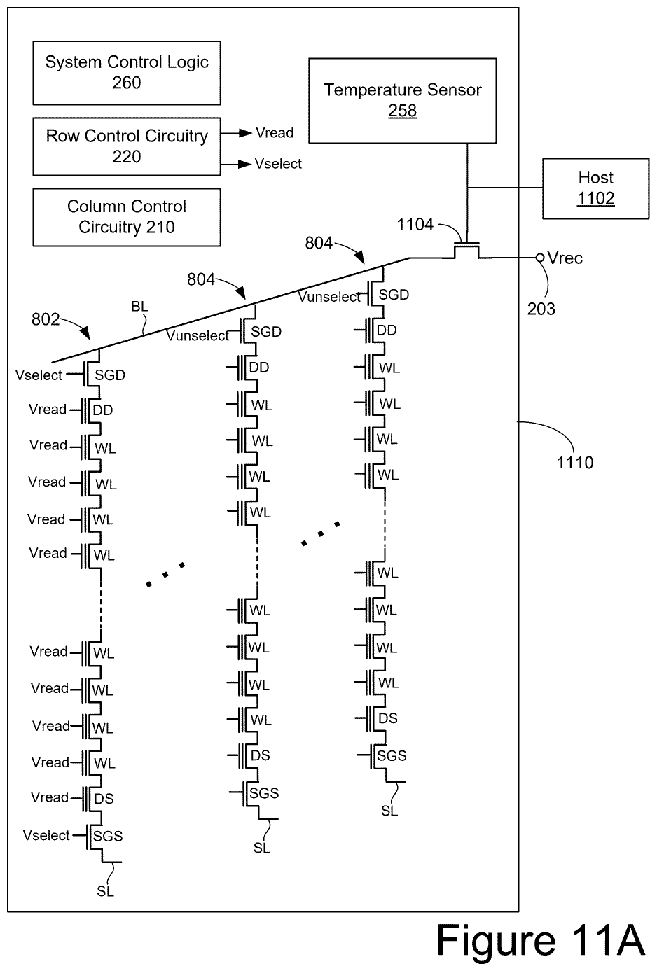

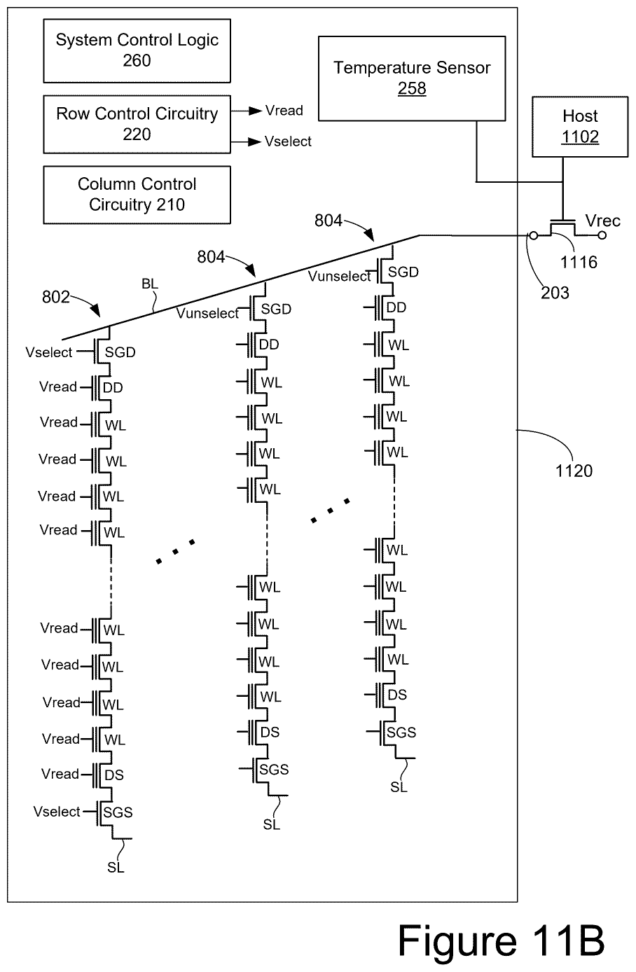

FIG. 11A depicts an embodiment of a system for recovery of NAND memory cells using self-heating by victim NAND strings. The system may be used to perform process 900, 1000, 1200 (described below) or 1300 (described below). One of the bit lines (BL) and a few victim NAND strings 802 are depicted. FIG. 11A depicts only a few of the many NAND strings that are associated with the bit line. The NAND strings and bit line are in the memory structure 202 (see FIGS. 2B and 2C). The example NAND strings are a simplified version of the NAND strings in FIG. 4E. The SGD may be used to connect the victim NAND strings 802 to the bit line in order to select the NAND string to be a victim NAND string. In this example, one victim NAND strings 802 is selected by applying Vselect to turn on the SGD transistor. Two target NAND strings 804 are depicted. The three NAND strings could be in the same block or different blocks. The SGS may be used to connect the victim NAND string 802 to the source line (SL). A read pass voltage (Vread) is applied to the control gates of the regular memory cells (WL) and the dummy memory cells (DD, DS) on the victim NAND string. The voltages may be applied to the word lines, SGD, and SGS by the row control circuitry 220, under control of the system control logic 260. The voltages on the regular memory cells (WL) and the dummy memory cells (DD, DS) for the target NAND strings are not depicted as those may be the same as those applied to the victim NAND string 802, but are not required to be the same. For example, if a victim NAND string 802 is in the same block as a target NAND string 804, then the victim NAND string 802 will be connected to word lines having Vread applied thereto.

Note that the target NAND strings 804 in FIG. 11A could be closer to a victim NAND string that is connected to a bit line that is not depicted in FIG. 11A, than to the victim NAND string that is depicted in FIG. 11A. However, the target NAND strings 804 are close enough to a victim NAND strings 802 to be heated sufficiently to remove trapped charges from the memory cells of the target NAND strings. The temperature sensor 258 is able to sense temperature in a region containing the target NAND strings. The temperature sensor 258 is typically on the same die as the target NAND strings. As noted above, the temperature sensor 258 may include a TCO BGR (band gap reference), which may be used for temperature dependent memory operations such as temperature dependent program operations and/or temperature dependent read operations.

In one embodiment, The NAND strings, the bit line, the system control logic 260, the row control circuitry 220, the column control circuity 210, and the temperature sensor 258 are all on the memory die 200. In one embodiment, The NAND strings, the bit line, the system control logic 260, the row control circuitry 220, the column control circuity 210, and the temperature sensor 258 are all in the integrated memory assembly 207. The memory die 200 or integrated memory assembly 207 are within storage 1110.

A switch 1104 (e.g., transistor) is used to connect the bit line to a voltage Vrec. In an embodiment, the voltage Vrec is applied to a pin/pad 203 or the like of the chip containing the victim NAND strings 802 and the target NAND strings. In an embodiment, Vrec has a magnitude of about 3V. The pin/pad 203 could be one that is used to provide a voltage to the NAND die. An example is a Vpp pin in the Open NAND Flash Interface (ONFI). The voltage Vrec is provided from a power source that is capable of providing a large enough current to heat the NAND to a target temperature (e.g., 250 degrees Celsius) for self-heating to remove the trapped charges from the memory cells on the target NAND strings. Note that the needed current to heat the NAND to a target temperature may depend on other factors, such as the magnitude of Vrec to the bit line, and the specific heat of materials in the NAND (e.g., polysilicon in victim NAND channels, SiO2 or other materials between the victim NAND strings and the target NAND strings).

In an embodiment of FIG. 11A, the switch 1104 is within the storage 1110. For example, the switch may be on the memory die 200 or the controller die 211. The switch 1104 has one terminal connected to the pin/pad 203, which receives Vrec. Thus, the switch 1104 can selectively pass Vrec from the pin/pad 203. A control circuit in the storage 1120 may route Vrec from the switch 1104 to the bit line. Note that the pathway between the switch 1104 to the bit line is simplified. The switch 1104 is controllable (directly or indirectly) by a host 1102 and/or the temperature sensor 258. The temperature sensor 258 could directly control the switch 1104. The temperature sensor 258 could send a signal to a control circuit (e.g., system control logic 260), which directly controls the switch 1104. The host 1102 is external to the storage 1110. The host 1102 is not necessarily the same host 102 as depicted in FIG. 2A. For example, the host 1102 could be the memory controller 120. Alternately, the host 1102 could be computer system in a facility used to refurbish NAND memory at the end of life. The host 1102 may directly control the switch 1104 or could send a signal to a control circuit (e.g., system control logic 260), which directly controls the switch 1104. Note that the pathway between the pin/pad 203 and the bit line may be a special pathway in view of the possibility of a larger current than would typically be used for operation of the NAND. For example, the switch 1104 may be a transistor that is capable of passing a higher current than would typically be used for operation of the NAND. The switch 1104 may include, but is not limited to, one or more MOSFETs (e.g., CMOS technology).

In one embodiment, the switch between Vrec and the bit line is external to the storage. FIG. 11B depicts an embodiment in which the switch 1116 is external to storage 1120. The switch 1116 has one terminal connected to the pin/pad 203 and another terminal that receives Vrec. Thus, the switch 1116 can selectively pass Vrec to the pin/pad 203. A control circuit in the storage 1120 may route Vrec from the pin/pad 203 to the bit line. Note that the pathway between the pin/pad 203 to the bit line is simplified. Storage 1120 is similar to storage 1110 in FIG. 11A. However, as noted the switch 1116 is external to the storage 1120. In an embodiment, the host 1102 directly controls the switch 1116. In one embodiment, the temperature sensor 258 may also control the external switch 1116. In another embodiment, there is also an internal switch on the storage that is controlled by the temperature sensor 258 (e.g., switch 1104 in FIG. 11A may be added to the configuration of FIG. 11B).

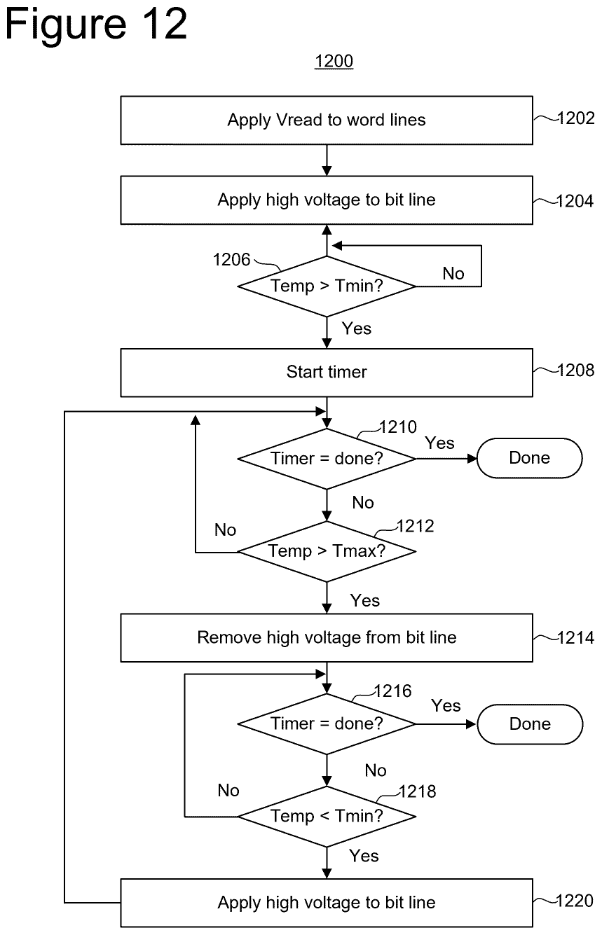

FIG. 12 is a flowchart of one embodiment of a process 1200 of self-heating NAND with victim NAND strings for recovery of memory cells on target NAND strings. Prior to process 1200 the process 1000 in FIG. 10 may be used to erase the memory cells on the victim NAND strings and program the memory cells on the target NAND strings. Process 1200 includes an embodiment in which the switch 1104/1116 is controlled based on the temperature in order to maintain the temperature within a target temperature range. As one example, the target temperature range may be from 225 degrees Celsius to 250 degrees Celsius.

Step 1202 includes applying Vread to the word lines connected to memory cells on the victim NAND strings. Applying Vread to the memory cells on the victim NAND strings 802 when those memory cells in the erased state facilitates generating a relatively high current in the victim NAND strings. Advantageously, applying Vread to all of the memory cells on the victim NAND strings is compatible with circuitry used for read operations. The circuitry used for read operations is configured to apply Vread to all of the unselected memory cells on NAND strings during a read or verify operation. Hence, the existing circuitry may be used in step 1202 to apply Vread to all memory cells on the victim NAND strings. Hence, there is no need for additional circuitry to generate voltages for the word lines.

Step 1204 includes a “high voltage” to the bit line. This high voltage may be about 3V, as one example. In an embodiment, this high voltage is provided from off chip. With reference to FIG. 11A, this high voltage may be Vrec applied to the pin/pad 203 while the switch 1104 is closed (e.g., transistor is on) to connect Vrec to the bit line. With reference to FIG. 11B, this high voltage may be Vrec applied to the switch 1116 while the switch 1116 is closed (e.g., transistor is on) to connect Vrec to the pin/pad 203. Also, a control circuit in storage 1110/1120 may route Vrec to the bit line.

Step 1206 includes a determination of whether the temperature has reached the lower limit (Tmin). The temperature sensor 258 may be used to sense the temperature. If the temperature has reached Tmin, then the timer is started in step 1208. This timer is used to determine when the memory cells have been heated for a sufficient time to provide a desired amount of charge de-trapping in the memory cells. The desired amount of charge de-trapping relates to the improvement in fail bit count, wherein improvement in fail bit count may be an end goal. Step 1210 includes a determination of whether the timer indicates that sufficient time has passed for the recovery procedure to end. Assuming more time is needed, then in step 1212 a determination is made of whether the temperature has reached the upper limit (Tmax).

If the temperature reaches the upper limit then the high voltage is removed from the bit line in step 1214. With reference to FIG. 11A, the high voltage may be removed by controlling the switch 1104 to prevent Vrec from reaching the bit line. With reference to FIG. 11B, the high voltage may be removed by controlling the switch 1116 to prevent Vrec from reaching the bit line. After the high voltage is removed from the bit line the temperature is expected to fall. Steps 1216 and 1218 include determining whether the timer is done (step 1216) and whether the temperature has fallen below the lower limit of Tmin (step 1218). If the timer indicates that sufficient time has passed (in step 1216), then the process may end. If the temperature falls below Tmin then the high voltage is once again applied to the bit line in step 1220. Step 1220 may include once again closing the switch 1104 (e.g., transistor is on) to connect Vrec to the bit line. The process 1200 then returns to steps 1210/1212 to test for whether the time is up (step 1210) and whether the upper temperature limit is reached (step 1212).

When the time is up the memory cells on the target NAND strings have had a sufficient amount of time with the temperature in the temperature range between the lower temperature limit and the upper temperature limit. Therefore, the memory cells on the target NAND strings have been heated for a sufficient amount of time to remove trapped charges. Therefore, the process 1200 provides for recovery of the memory cells on the target NAND strings from excessive wear.

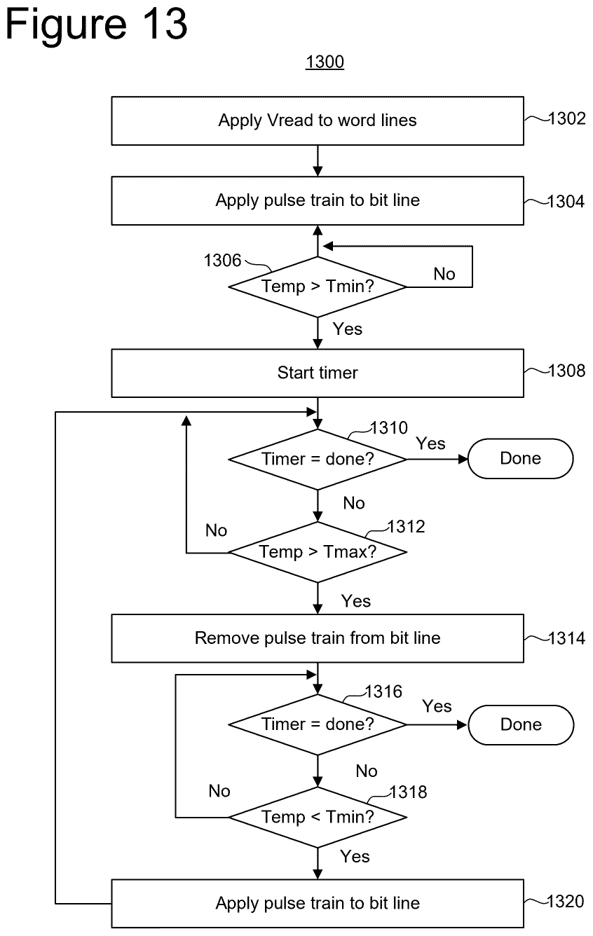

FIG. 13 is a flowchart of one embodiment of a process 1300 of self-heating NAND with victim NAND strings for recovery of memory cells on target NAND strings. Prior to process 1300 the process 1300 in FIG. 10 may be used to erase the memory cells on the victim NAND strings and program the memory cells on the target NAND strings. Process 1300 includes an embodiment in which the switch 1104 is controlled based on the temperature in order to maintain the temperature within a target temperature range. As one example, the target temperature range may be from 225 degrees Celsius to 250 degrees Celsius. Process 1300 differs from process 1200 in that a pulse train is applied to and removed from the bit line responsive to the temperature as opposed to a steady voltage. Steps in process 1300 that are similar to corresponding steps in process 1200 will be described only briefly.

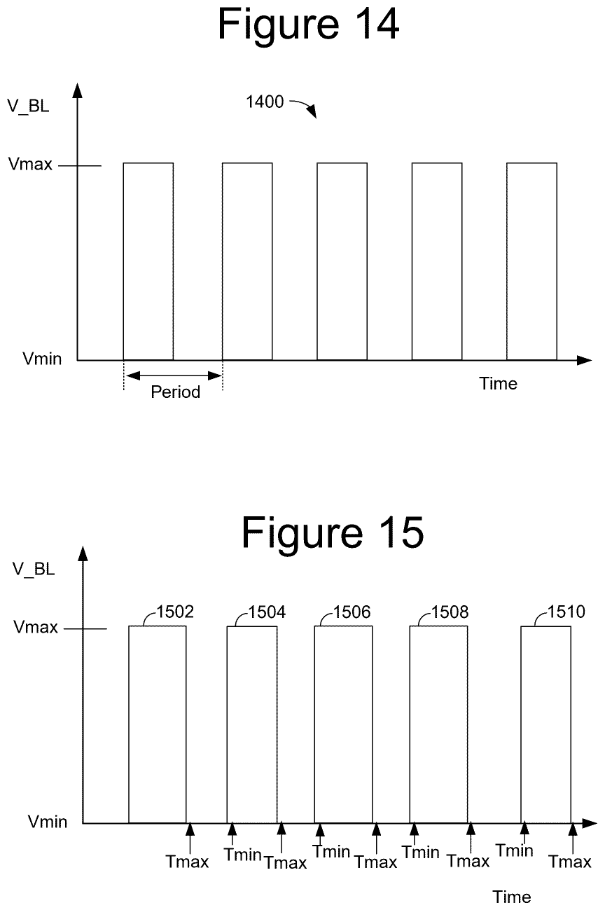

Step 1302 includes applying Vread to the word lines connected to memory cells on the victim NAND strings. Step 1304 includes a “pulse train” to the bit line. FIG. 14 shows an example pulse train 1400 that oscillates between a Vmax and Vmin. As an example, Vmax may be 3V and Vmin may be 0V. In an embodiment, the pulse train is provided by applying Vrec to the pin/pad 203 while the switch 1104 (see FIG. 11A) is closed/opened by the host 1102 at the desired period and duty cycle. In an embodiment, the pulse train is provided by applying Vrec to the switch 1116 (see FIG. 11B) with the host closing/opening the switch 1116 at the desired period and duty cycle. In one embodiment, the pulse width is chosen to allow the channel of the victim NAND string sufficient time to reach a target temperature (e.g., 250 degrees Celsius), but to not exceed the target temperature by a significant amount. The time for the channel of the victim NAND string to reach the target temperature will depend on factors such as the voltage from bit line to source line, NAND channel current, and the specific heat of the material of the NAND channel. An example material for the NAND channel is polysilicon, but another material may be used. As noted, the time for the channel of the victim NAND string to reach the target temperature depends on a variety of factors, but the target temperature could be reached in a relatively short time, such as about a microsecond. It will take additional time for the heat to spread to the target NAND strings.

Step 1306 includes a determination of whether the temperature has reached the lower limit (Tmin). If so, then the timer is started in step 1308. This timer is used to determine when the memory cells have been heated for a sufficient time to provide a significant amount of charge de-trapping in the memory cells. Step 1310 includes a determination of whether the timer indicates that sufficient time has passed for the recovery procedure to end. Assuming more time is needed, then in step 1312 a determination is made of whether the temperature has reached the upper limit (Tmax).

If the temperature reaches the upper limit then the pulse train is removed from the bit line in step 1314. With reference to FIG. 11, the pulse train may be removed by controlling the switch 1104 to remove Vrec from reaching the bit line. In an embodiment, the temperature sensor 258 controls the switch 1104/1116 to prevent Vrec from reaching the bit line. After the pulse train is removed from the bit line the temperature is expected to fall. Steps 1316 and 1318 include determining whether the timer is done (step 1316) and whether the temperature has fallen below the lower limit of Tmin (step 1318). If the timer indicates that sufficient time has passed (in step 1316), then the process may end. If the temperature falls below Tmin then the pulse train is once again applied to the bit line in step 1320. Step 1320 may include once again closing the switch 1104 (e.g., transistor is on) to connect Vrec to the bit line. The process 1300 then returns to steps 1310/1312 to test for whether the time is up (step 1310) and whether the upper temperature limit is reached (step 1312).

When the time is up the memory cells on the target NAND strings have had a sufficient amount of time with the temperature in the temperature range between the lower temperature limit and the upper temperature limit. Therefore, the memory cells on the target NAND strings have been heated for a sufficient amount of time to remove trapped charges. Therefore, the process 1300 provides for recovery of the memory cells on the target NAND strings from excessive wear.

FIG. 15 depicts example signals that may be applied to the bit line in an embodiment. These signals are consistent with an embodiment of the process 1200 in FIG. 12. A sequence of five signals 1502, 1504, 1506, 1508, and 1510 are depicted. Each signal has a high voltage (Vmax) and a low voltage (Vmin). An example for Vmax is 3V and an example for Vmin is 0V. The first signal 1502 begins at the start of the process 1200 (e.g., step 1204. Each signal ends when the temperature reaches Tmax (e.g., when step 1212 indicates the temperature is at Tmax). Thus the end of each signal may correspond to step 1214. The second and additional signals start when the temperature has fallen to at Tmin (step 1218). Thus the start of second and additional signals may correspond to step 1220.

In an embodiment, each signal 1502-1510 in FIG. 15 is a pulse train 1400 as depicted in FIG. 14. Thus, if the signals in FIG. 15 are pulse trains (such as pulse train 1400) then these signals are consistent with an embodiment of the process 1300 in FIG. 13. The first signal 1502 begins at the start of the process 1300 (e.g., step 1304). Each signal ends when the temperature reaches Tmax (e.g., when step 1312 indicates the temperature is at Tmax). Thus the end of each signal may correspond to step 1314. The second and additional signals start when the temperature has fallen to at Tmin (step 1318). Thus the start of second and additional signals may correspond to step 1320.

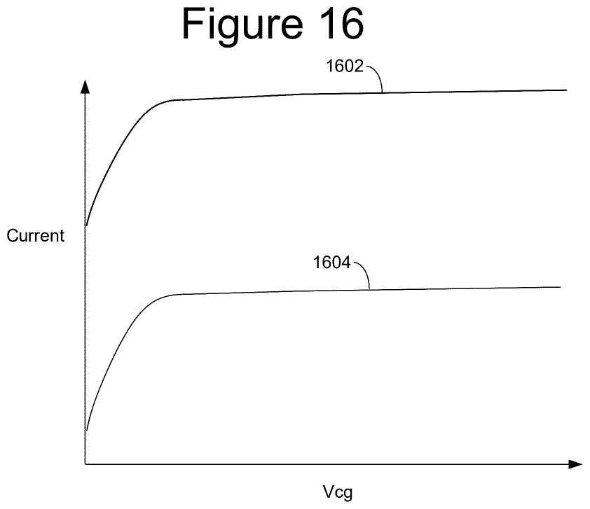

FIG. 16 depicts victim NAND string current versus control gate voltage for erased cells and a random pattern. Plot 1602 shows victim NAND string current versus control gate voltage if all of the memory cells on the victim NAND string are erased. Plot 1604 shows victim NAND string current versus control gate voltage if the memory cells on the victim NAND string are in a random pattern. Substantially more current may be generated if the memory cells are erased than in a random pattern. Note that an example was presented in FIGS. 11A and 11B in which Vread is applied to the control gate (Vcg). The current may saturate even if Vcg is below Vread. Thus, it will be understood that it is not a requirement to apply a voltage as great as Vread to the control gates of the memory cells on the victim NAND strings.

In view of the foregoing, an embodiment includes a system comprising a three-dimensional memory structure having NAND strings with memory cells. The NAND strings each comprising a NAND channel. The memory structure has bit lines associated with the NAND strings. The system includes one or more control circuits in communication with the memory structure. The one or more control circuits include a temperature sensor configured to sense a temperature of the memory structure. The one or more control circuits are configured to create a current through the NAND channel of one or more victim NAND strings in the memory structure to heat a region of the memory structure having target NAND strings. The one or more control circuits are configured to regulate the current through the NAND channel of each of the one or more victim NAND strings to maintain temperature of the region of the memory structure to a target range of temperatures for a period of time to remove trapped charges from the memory cells on the target NAND strings.

In an embodiment of the system, the one or more control circuits are configured to apply a voltage to a bit line or bit lines connected to the one or more victim NAND strings while applying a voltage to control gates of the memory cells on the one or more victim NAND strings to create the current through the NAND channel of each of the one or more victim NAND strings.

In an embodiment of the system, the one or more control circuits are configured to control a magnitude of the voltage to the bit line or bit lines connected to the one or more victim NAND strings responsive to the temperature to regulate the current through the NAND channel of each of the one or more victim NAND strings to maintain the temperature of the region to the target range of temperatures.

An embodiment of the system further comprises a memory controller interface having a set of external pins. The one or more control circuits are configured to route a voltage received on a first pin of the set of external pins to the bit line or bit lines as the voltage for creating the current through the NAND channel of each of the one or more victim NAND strings.

An embodiment of the system further comprises a memory controller interface having a set of external pins and a switch between a first pin of the set of external pins and the bit line or bit lines. The switch is configured to selectively pass a voltage on the first pin. The one or more control circuits are configured to control the switch to selectively pass the voltage on the first pin from the switch to the bit line or bit lines as the voltage for creating the current through the NAND channel of each of the one or more victim NAND strings.

An embodiment of the system further comprises a memory controller interface having a set of external pins and a switch connected to a first pin of the set of external pins. The switch is configured to selectively pass a voltage received by the switch to the first pin. The one or more control circuits are configured to route the voltage selectively passed from the switch to the first pin to the bit line or bit lines as the voltage for creating the current through the NAND channel of each or more victim NAND strings.

An embodiment of the system further comprises a switch configured to selectively pass a voltage. The temperature sensor is configured to control the switch responsive to the temperature of the region of the memory structure to selectively pass the voltage to the bit line or the bit lines connected to the one or more victim NAND strings to regulate the current through the NAND channel of each of the one or more victim NAND strings.

An embodiment of the system further comprises a switch configured to selectively pass a voltage and a host configured to control the switch to selectively pass the voltage to the bit line or the bit lines connected to the one or more victim NAND strings to regulate the current through the NAND channel of each of the one or more victim NAND strings.

In an embodiment of the system the one or more control circuits are configured to select the one or more victim NAND strings from a set of column redundancy bits.

In an embodiment of the system the memory cells of the NAND strings each have a charge trap layer and a tunneling layer between the charge trap layer and the channel of the NAND string. And the one or more control circuits regulate the current through the NAND channel of each of the one or more victim NAND strings to maintain the temperature of the region of the memory structure within the target range of temperatures for the period of time to remove trapped charges from the tunneling layers of the memory cells on the target NAND strings.

In an embodiment of the system the one or more control circuits are further configured to erase the one or more victim NAND strings prior to creating the current through the one or more victim NAND strings, wherein the one or more victim NAND strings are in an erased state while creating the current through the NAND channel of each of the one or more victim NAND strings to heat the region of the memory structure.

In an embodiment of the system the one or more control circuits are further configured to program the memory cells on the target NAND strings prior to creating the current through the one or more victim NAND strings. The memory cells on the target NAND strings are in a programmed state while creating the current through the NAND channel of each of the one or more victim NAND strings to heat the region of the memory structure.

An embodiment includes a method for recovering NAND from excessive wear. The method comprises selecting a victim NAND string in a three-dimensional NAND memory structure. The victim NAND string having a channel. The method comprises applying a first voltage to a bit line connected to the victim NAND string while applying a second voltage to control gates of memory cells on the victim NAND string to generate a current through the channel of the victim NAND string to heat a region of the memory structure having target NAND strings. The method comprises regulating the first voltage to the bit line to maintain temperature of the region to a target range of temperatures for a period of time to recover fail bits due to trapped charges in tunneling layers of the memory cells on the target NAND strings.

An embodiment includes a system comprising a semiconductor die having a memory structure having alternating layers of conductive material and insulating material and NAND strings extending through the alternating layers of conductive material and insulating material. The NAND strings each comprise a NAND channel. The NAND strings comprise memory cells each having a charge trap layer and a tunneling layer between the charge trap layer and the NAND channel. The memory structure has bit lines associated with the NAND strings. The system comprises one or more control circuits in communication with the memory structure. The one or more control circuits include a temperature sensor configured to sense a temperature on the semiconductor die. The one or more control circuits are configured to apply a voltage to a bit line connected to a victim NAND string while applying voltages to control gates of memory cells on the victim NAND strings to generate a current through the NAND channel of the victim NAND string to heat a region of the memory structure having target NAND strings. The one or more control circuits are configured to regulate the voltage to the bit line responsive to the temperature on the semiconductor die to maintain temperature on the semiconductor die within a target range of temperatures for a period of time to remove trapped charges from the tunneling layers of the memory cells on the target NAND strings.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects. For example, a “set of reference voltages” may contain one or more reference voltages.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A system comprising:
a three-dimensional memory structure having NAND strings with memory cells, the NAND strings each comprising a NAND channel, the memory structure having bit lines associated with the NAND strings; and
one or more control circuits in communication with the memory structure, the one or more control circuits including a temperature sensor configured to sense a temperature of the memory structure, the one or more control circuits configured to:
create a current through the NAND channel of one or more victim NAND strings in the memory structure to heat a region of the memory structure having target NAND strings; and
regulate the current through the NAND channel of each of the one or more victim NAND strings to maintain temperature of the region of the memory structure to a target range of temperatures for a period of time to remove trapped charges from the memory cells on the target NAND strings.

2. The system of claim 1, wherein the one or more control circuits are configured to apply a voltage to a bit line or bit lines connected to the one or more victim NAND strings while applying a voltage to control gates of the memory cells on the one or more victim NAND strings to create the current through the NAND channel of each of the one or more victim NAND strings.

3. The system of claim 2, wherein the one or more control circuits are configured to control a magnitude of the voltage to the bit line or bit lines connected to the one or more victim NAND strings responsive to the temperature to regulate the current through the NAND channel of each of the one or more victim NAND strings to maintain the temperature of the region to the target range of temperatures.

4. The system of claim 2, further comprising a memory controller interface having a set of external pins, wherein the one or more control circuits are configured to route a voltage received on a first pin of the set of external pins to the bit line or bit lines as the voltage for creating the current through the NAND channel of each of the one or more victim NAND strings.

5. The system of claim 1, further comprising:
a memory controller interface having a set of external pins; and
a switch between a first pin of the set of external pins and the bit line or bit lines, the switch is configured to selectively pass a voltage on the first pin, wherein the one or more control circuits are configured to control the switch to selectively pass the voltage on the first pin from the switch to the bit line or bit lines as the voltage for creating the current through the NAND channel of each of the one or more victim NAND strings.

6. The system of claim 1, further comprising:
a memory controller interface having a set of external pins; and
a switch connected to a first pin of the set of external pins, the switch configured to selectively pass a voltage received by the switch to the first pin, wherein the one or more control circuits are configured to route the voltage selectively passed from the switch to the first pin to the bit line or bit lines as the voltage for creating the current through the NAND channel of each or more victim NAND strings.

7. The system of claim 1, wherein:
the system further comprises a switch configured to selectively pass a voltage; and
the temperature sensor is configured to control the switch responsive to the temperature of the region of the memory structure to selectively pass the voltage to the bit line or the bit lines connected to the one or more victim NAND strings to regulate the current through the NAND channel of each of the one or more victim NAND strings.

8. The system of claim 1, wherein the system further comprises:
a switch configured to selectively pass a voltage; and
a host configured to control the switch to selectively pass the voltage to the bit line or the bit lines connected to the one or more victim NAND strings to regulate the current through the NAND channel of each of the one or more victim NAND strings.

9. The system of claim 1, wherein the one or more control circuits are configured to select the one or more victim NAND strings from a set of column redundancy bits.

10. The system of claim 1, wherein:
the memory cells of the NAND strings each have a charge trap layer and a tunneling layer between the charge trap layer and the channel of the NAND string; and
the one or more control circuits regulate the current through the NAND channel of each of the one or more victim NAND strings to maintain the temperature of the region of the memory structure within the target range of temperatures for the period of time to remove trapped charges from the tunneling layers of the memory cells on the target NAND strings.

11. The system of claim 1, wherein the one or more control circuits are further configured to:
erase the one or more victim NAND strings prior to creating the current through the one or more victim NAND strings, wherein the one or more victim NAND strings are in an erased state while creating the current through the NAND channel of each of the one or more victim NAND strings to heat the region of the memory structure.

12. The system of claim 11, wherein the one or more control circuits are further configured to:
program the memory cells on the target NAND strings prior to creating the current through the one or more victim NAND strings, wherein the memory cells on the target NAND strings are in a programmed state while creating the current through the one or more victim NAND strings to heat the region of the memory structure.

13. A method for recovering NAND from excessive wear, the method comprising:
selecting a victim NAND string in a three-dimensional NAND memory structure, the victim NAND string having a channel;
applying a first voltage to a bit line connected to the victim NAND string while applying a second voltage to control gates of memory cells on the victim NAND string to generate a current through the channel of the victim NAND string to heat a region of the memory structure having target NAND strings; and
regulating the first voltage to the bit line to maintain temperature of the region to a target range of temperatures for a period of time to recover fail bits due to trapped charges in tunneling layers of the memory cells on the target NAND strings.

14. The method of claim 13, further comprising:
erasing the victim NAND string prior to applying the first voltage to a bit line, wherein the victim NAND string is in an erased state while regulating the first voltage to the bit line.

15. The method of claim 13, wherein selecting the victim NAND comprises selecting the victim NAND from a group of NAND strings that are ineligible to store user data.

16. A system comprising:
a semiconductor die having a memory structure having alternating layers of conductive material and insulating material and NAND strings extending through the alternating layers of conductive material and insulating material, the NAND strings each comprising a NAND channel, the NAND strings comprising memory cells each having a charge trap layer and a tunneling layer between the charge trap layer and the NAND channel, the memory structure having bit lines associated with the NAND strings; and
one or more control circuits in communication with the memory structure, the one or more control circuits including a temperature sensor configured to sense a temperature on the semiconductor die, the one or more control circuits configured to:
apply a voltage to a bit line connected to a victim NAND string while applying voltages to control gates of memory cells on the victim NAND strings to generate a current through the NAND channel of the victim NAND string to heat a region of the memory structure having target NAND strings; and
regulate the voltage to the bit line responsive to the temperature on the semiconductor die to maintain temperature on the semiconductor die within a target range of temperatures for a period of time to remove trapped charges from the tunneling layers of the memory cells on the target NAND strings.

17. The system of claim 16, wherein the one or more control circuits are further configured to:
erase the victim NAND string prior to applying the voltage to the bit line connected to the victim NAND string, wherein the victim NAND string is in an erased state while regulating the voltage to the bit line.

18. The system of claim 16, further comprising:
a memory controller interface having a set of external pins; and
a transistor between a first pin of the set of external pins and the bit line, the transistor configured to selectively pass a voltage on the first pin, wherein the one or more control circuits are configured to control the transistor responsive to temperature sensed by the temperature sensor to selectively pass the voltage on the first pin from the transistor to the bit line to regulate the voltage to the bit line responsive to the temperature.

19. The system of claim 16, further comprising:
a memory controller interface having a set of external pins; and
a transistor connected to a first pin of the set of external pins and the bit line, the transistor configured to selectively pass a voltage to the first pin, wherein the one or more control circuits are configured to control the transistor to provide the voltage from the transistor to the first pin as a pulse train, the one or more circuits are configured to pass the pulse train from the first pin to the bit line.

20. The system of claim 16, wherein the one or more control circuits are configured to select the one or more victim NAND strings from a set of column redundancy bits.
